(19) United States
(12) Patent Application Publication
(10) Pub. No.: US 2025/0130877 A1
(43) Pub. Date: Apr. 24, 2025

(54) Handling Faulty Usage-Based-Disturbance Data

(71) Applicant: Micron Technology, Inc., Boise, ID (US)

(72) Inventors: Yang Lu, Boise, ID (US); Mark Kalei Hadrick, Boise, ID (US); Kang-Yong Kim, Boise, ID (US); Donald Morgan, Meridian, ID (US); Victor Wong, Boise, ID (US)

(73) Assignee: Micron Technology, Inc., Boise, ID (US)

(21) Appl. No.: 18/790,795

(22) Filed: Jul. 31, 2024

Related U.S. Application Data
(60) Provisional application No. 63/592,761, filed on Oct. 24, 2023.

(51) Int. Cl. G06F 11/07

(52) U.S. Cl. CPC G06F 11/0772; G06F 11/073

(57) ABSTRACT

Apparatuses and techniques for handling faulty usage-based-disturbance data are described. In an example aspect, a memory device uses a report flag to indicate that an address of a row that corresponds to the faulty usage-based-disturbance data is logged at a global-bank level and is accessible by a host device. The report flag also enables the memory device to avoid reporting another error until the host device has cleared information associated with a previously-reported error. In another example aspect, the memory device temporarily prevents usage-based-disturbance mitigation from being performed based on the faulty usage-based-disturbance data. This means that if the faulty usage-based-disturbance data would otherwise trigger refreshing of one or more rows that are proximate to the row corresponding to the faulty usage-based-disturbance data, the memory device does not perform these refresh operations. This is beneficial by conserving resources for refreshing victim rows that are identified based on valid usage-based-disturbance data.

### CROSS-REFERENCE TO RELATED APPLICATION(S)

This application claims the benefit of U.S. Provisional Patent Application Ser. No. 63/592,761, filed on Oct. 24, 2023, the disclosure of which is incorporated by reference herein in its entirety.

### BACKGROUND

Computers, smartphones, and other electronic devices rely on processors and memories. A processor executes code based on data to run applications and provide features to a user. The processor obtains the code and the data from a memory. The memory in an electronic device can include volatile memory (e.g., random-access memory (RAM)) and non-volatile memory (e.g., flash memory). Like the capabilities of a processor, the capabilities of a memory can impact the performance of an electronic device. This performance impact can increase as processors are developed that execute code faster and as applications operate on increasingly larger data sets that require ever-larger memories.

### BRIEF DESCRIPTION OF THE DRAWINGS

Apparatuses of and techniques for reporting faulty usage-based-disturbance data are described with reference to the following drawings. The same numbers are used throughout the drawings to reference like features and components:

FIG. 1 illustrates example apparatuses that can implement aspects of handling faulty usage-based-disturbance data;

FIG. 2 illustrates an example computing system that can implement aspects of handling faulty usage-based-disturbance data;

FIG. 3 illustrates example data stored within rows of a memory array;

FIG. 4 illustrates an example memory device in which aspects of handling faulty usage-based-disturbance data may be implemented;

FIG. 5 illustrates an example arrangement of usage-based-disturbance data repair circuitry on a die;

FIG. 6 illustrates an example of usage-based-disturbance data repair circuitry coupled to an alert circuit for implementing aspects of handling faulty usage-based-disturbance data;

FIG. 7 illustrates an example implementation of usage-based-disturbance data repair circuitry directly logging a memory address associated with faulty usage-based-disturbance data;

FIG. 8 illustrates an example implementation of usage-based-disturbance data repair circuitry indirectly logging a memory address associated with faulty usage-based-disturbance data;

FIG. 9 illustrates first example implementations of detection circuits for indirectly logging a memory address associated with faulty usage-based-disturbance data;

FIG. 10 illustrates second example implementations of detection circuits for indirectly logging a memory address associated with faulty usage-based-disturbance data;

FIG. 11 illustrates third example implementations of detection circuits for indirectly logging a memory address associated with faulty usage-based-disturbance data;

FIG. 12 illustrates example implementations of usage-based-disturbance data repair circuitry and a mode register for handling faulty usage-based-disturbance data;

FIG. 13 illustrates an example scheme for handling faulty usage-based-disturbance data;

FIG. 14 illustrates an example system that includes a host device and a memory device that is capable of implementing aspects of handling faulty usage-based-disturbance data;

FIG. 15 illustrates an example method of a memory device performing aspects of logging a memory address associated with faulty usage-based-disturbance data; and

FIG. 16 illustrates an example method of a memory device performing aspects of reporting faulty usage-based-disturbance data.

### DETAILED DESCRIPTION

### Overview

Processors and memory work in tandem to provide features to users of computers and other electronic devices. As processors and memory operate more quickly together in a complementary manner, an electronic device can provide enhanced features, such as high-resolution graphics and artificial intelligence (AI) analysis. Some applications, such as those for financial services, medical devices, and advanced driver assistance systems (ADAS), can also demand more-reliable memories. These applications use increasingly reliable memories to limit errors in financial transactions, medical decisions, and object identification. However, in some implementations, more-reliable memories can sacrifice bit densities, power efficiency, and simplicity.

To meet the demands for physically smaller memories, memory devices can be designed with higher chip densities. Increasing chip density, however, can increase the electromagnetic coupling (e.g., capacitive coupling) between adjacent or proximate rows of memory cells due, at least in part, to a shrinking distance between these rows. With this undesired coupling, activation (or charging) of a first row of memory cells can sometimes negatively impact a second nearby row of memory cells. In particular, activation of the first row can generate interference, or crosstalk, that causes the second row to experience a voltage fluctuation. In some instances, this voltage fluctuation can cause a state (or value) of a memory cell in the second row to be incorrectly determined by a sense amplifier. Consider an example in which a state of a memory cell in the second row is a “1.” In this example, the voltage fluctuation can cause a sense amplifier to incorrectly determine the state of the memory cell to be a “0” instead of a “1.” Left unchecked, this interference can lead to memory errors or data loss within the memory device.

In some circumstances, a particular row of memory cells is activated repeatedly in an unintentional or intentional (sometimes malicious) manner. Consider, for instance, that memory cells in an R^{th} row are subjected to repeated activation, which causes one or more memory cells in a proximate row (e.g., within an R+1 row, an R+2 row, an R-1 row, and/or an R-2 row) to change states. This effect is referred to as usage-based disturbance. The occurrence of usage-based disturbance can lead to the corruption or changing of contents within the affected row of memory.

Some memory devices utilize circuits that can detect usage-based disturbance and mitigate its effects. To monitor for usage-based disturbance, a memory device can store an activation count within each row of a memory array. The activation count keeps track of a quantity of accesses or activations of the corresponding memory row. If the activation count meets or exceeds a threshold (e.g., a mitigation threshold), proximate rows, including one or more adjacent rows, may be at increased risk for data corruption due to the repeated activations of the accessed row and the usage-based disturbance effect. To manage this risk to the affected rows, the memory device can refresh the proximate rows.

The effectiveness of this protective feature is jeopardized, however, if an activation count malfunctions or is otherwise faulty. The activation count, for instance, can become corrupted when read or written during the array counter update procedure. In another aspect, the memory cells that store the activation count can fail to retain the stored value of the activation count.

The memory device can perform a repair process that replaces a faulty activation count in a permanent (or “hard”) manner or in a temporary (or “soft”) manner. The repair process, however, is initiated by a host device (or a memory controller). In some implementations, the host device may not have the means to directly detect the faulty activation count. Without the ability to write to or read from the memory cells that store the activation count, for instance, the host device may be unable to assess whether or not the activation count is faulty. Consequently, the host device may be unable to initiate the repair process when an activation count becomes faulty.

To address this and other issues regarding usage-based disturbance, this document describes techniques for handling faulty usage-based-disturbance data. In an example aspect, a memory device stores usage-based-disturbance data within a subset of memory cells of multiple rows of a memory array. The memory device can detect, at a local-bank level, a fault associated with the usage-based-disturbance data. This detection enables the memory device to log an address associated with the faulty usage-based-disturbance data. To avoid increasing a complexity and/or a size of the memory device, some implementations of the memory device can perform the address logging at the global-bank level with the assistance of an engine, such as a test engine. The memory device stores the logged address in at least one mode register to communicate the fault to a memory controller. With the logged address, the memory controller can initiate a repair procedure to fix the faulty usage-based-disturbance data.

In another example aspect, the memory device generates a report flag, which can indicate that the address of the row that corresponds to the faulty usage-based-disturbance data is logged at the global-bank level and can be accessed by the host device. The memory device can also use the report flag to ensure one error is reported at a time. In this case, the report flag prevents the memory device from reporting another error until the host device has cleared information associated with a previously-reported error.

In yet another example aspect, the memory device temporarily prevents usage-based-disturbance mitigation from being performed based on the faulty usage-based-disturbance data. This means that if the faulty usage-based-disturbance data would otherwise trigger refreshing of one or more rows that are proximate to the row corresponding to the faulty usage-based-disturbance data, the memory device does not perform these refresh operations. This is beneficial as it conserves resources for refreshing victim rows that are identified based on valid usage-based-disturbance data. After the host initiates a repair procedure that addresses the faulty usage-based-disturbance data, the memory device can return to monitoring and referencing the repaired usage-based-disturbance data.

### Example Operating Environments

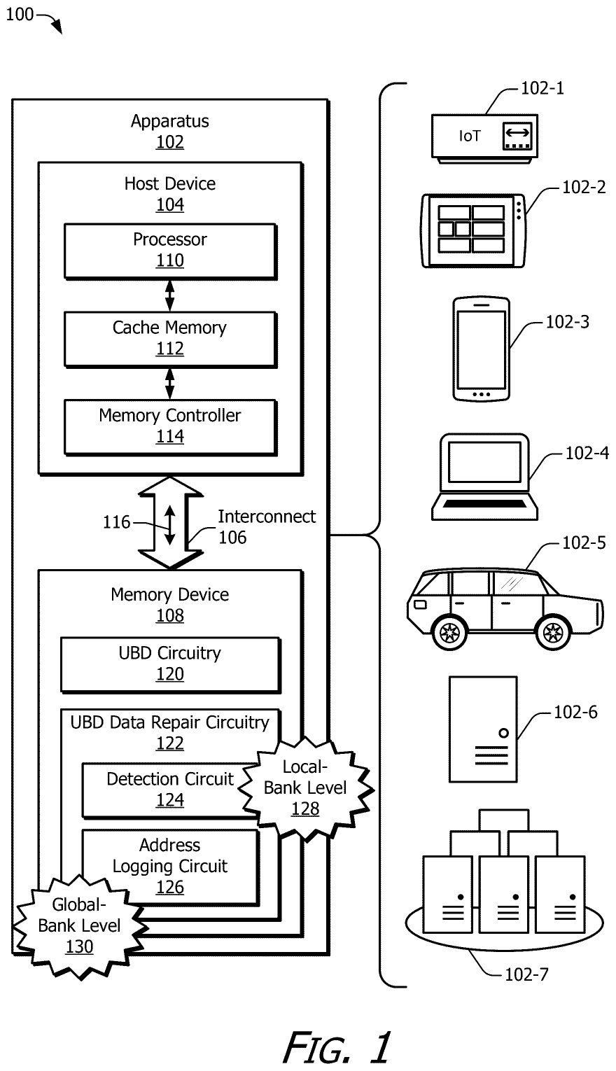

FIG. 1 illustrates, at 100 generally, an example operating environment including an apparatus 102 that can implement aspects of handling faulty usage-based-disturbance data. The apparatus 102 can include various types of electronic devices, including an internet-of-things (IoT) device 102-1, tablet device 102-2, smartphone 102-3, notebook computer 102-4, passenger vehicle 102-5, server computer 102-6, and server cluster 102-7 that may be part of cloud computing infrastructure, a data center, or a portion thereof (e.g., a printed circuit board (PCB)). Other examples of the apparatus 102 include a wearable device (e.g., a smartwatch or intelligent glasses), entertainment device (e.g., a set-top box, video dongle, smart television, a gaming device), desktop computer, motherboard, server blade, consumer appliance, vehicle, drone, industrial equipment, security device, sensor, or the electronic components thereof. Each type of apparatus can include one or more components to provide computing functionalities or features.

In example implementations, the apparatus 102 can include at least one host device 104, at least one interconnect 106, and at least one memory device 108. The host device 104 can include at least one processor 110, at least one cache memory 112, and a memory controller 114. The memory device 108, which can also be realized with a memory module, can include, for example, a dynamic random-access memory (DRAM) die or module (e.g., Low-Power Double Data Rate synchronous DRAM (LPDDR SDRAM)). The DRAM die or module can include a three-dimensional (3D) stacked DRAM device, which may be a high-bandwidth memory (HBM) device or a hybrid memory cube (HMC) device. The memory device 108 can operate as a main memory for the apparatus 102. Although not illustrated, the apparatus 102 can also include storage memory. The storage memory can include, for example, a storage-class memory device (e.g., a flash memory, hard disk drive, solid-state drive, phase-change memory (PCM), or memory employing 3D XPoint™).

The processor 110 is operatively coupled to the cache memory 112, which is operatively coupled to the memory controller 114. The processor 110 is also coupled, directly or indirectly, to the memory controller 114. The host device 104 may include other components to form, for instance, a system-on-a-chip (SoC). The processor 110 may include a general-purpose processor, central processing unit, graphics processing unit (GPU), neural network engine or accelerator, application-specific integrated circuit (ASIC), field-programmable gate array (FPGA) integrated circuit (IC), or communications processor (e.g., a modem or baseband processor).

In operation, the memory controller 114 can provide a high-level or logical interface between the processor 110 and at least one memory (e.g., an external memory). The memory controller 114 may be realized with any of a variety of suitable memory controllers (e.g., a double-data-rate (DDR) memory controller that can process requests for data stored on the memory device 108). Although not shown, the host device 104 may include a physical interface (PHY) that transfers data between the memory controller 114 and the memory device 108 through the interconnect 106. For example, the physical interface may be an interface that is compatible with a DDR PHY Interface (DFI) Group interface protocol. The memory controller 114 can, for example, receive memory requests from the processor 110 and provide the memory requests to external memory with appropriate formatting, timing, and reordering. The memory controller 114 can also forward to the processor 110 responses to the memory requests received from external memory.

The host device 104 is operatively coupled, via the interconnect 106, to the memory device 108. In some examples, the memory device 108 is connected to the host device 104 via the interconnect 106 with an intervening buffer or cache. The memory device 108 may operatively couple to storage memory (not shown). The host device 104 can also be coupled, directly or indirectly via the interconnect 106, to the memory device 108 and the storage memory. The interconnect 106 and other interconnects (not illustrated in FIG. 1) can transfer data between two or more components of the apparatus 102. Examples of the interconnect 106 include a bus (e.g., a unidirectional or bidirectional bus), switching fabric, or one or more wires that carry voltage or current signals. The interconnect 106 can propagate one or more communications 116 between the host device 104 and the memory device 108. For example, the host device 104 may transmit a memory request to the memory device 108 over the interconnect 106. Also, the memory device 108 may transmit a corresponding memory response to the host device 104 over the interconnect 106.

The illustrated components of the apparatus 102 represent an example architecture with a hierarchical memory system. A hierarchical memory system may include memories at different levels, with each level having memory with a different speed or capacity. As illustrated, the cache memory 112 logically couples the processor 110 to the memory device 108. In the illustrated implementation, the cache memory 112 is at a higher level than the memory device 108. A storage memory, in turn, can be at a lower level than the main memory (e.g., the memory device 108). Memory at lower hierarchical levels may have a decreased speed but increased capacity relative to memory at higher hierarchical levels.

The apparatus 102 can be implemented in various manners with more, fewer, or different components. For example, the host device 104 may include multiple cache memories (e.g., including multiple levels of cache memory) or no cache memory. In other implementations, the host device 104 may omit the processor 110 or the memory controller 114. A memory (e.g., the memory device 108) may have an “internal” or “local” cache memory. As another example, the apparatus 102 may include cache memory between the interconnect 106 and the memory device 108. Computer engineers can also include any of the illustrated components in distributed or shared memory systems.

Computer engineers may implement the host device 104 and the various memories in multiple manners. In some cases, the host device 104 and the memory device 108 can be disposed on, or physically supported by, a printed circuit board (e.g., a rigid or flexible motherboard). The host device 104 and the memory device 108 may additionally be integrated together on an integrated circuit or fabricated on separate integrated circuits and packaged together. The memory device 108 may also be coupled to multiple host devices 104 via one or more interconnects 106 and may respond to memory requests from two or more host devices 104. Each host device 104 may include a respective memory controller 114, or the multiple host devices 104 may share a memory controller 114. This document describes with reference to FIG. 1 an example computing system architecture having at least one host device 104 coupled to a memory device 108.

Two or more memory components (e.g., modules, dies, banks, or bank groups) can share the electrical paths or couplings of the interconnect 106. The interconnect 106 can include at least one command-and-address bus (CA bus) and at least one data bus (DQ bus). The command-and-address bus can transmit addresses and commands from the memory controller 114 of the host device 104 to the memory device 108, which may exclude propagation of data. The data bus can propagate data between the memory controller 114 and the memory device 108. The memory device 108 may also be implemented as any suitable memory including, but not limited to, DRAM, SDRAM, three-dimensional (3D) stacked DRAM, DDR memory, or LPDDR memory (e.g., LPDDR DRAM or LPDDR SDRAM).

The memory device 108 can form at least part of the main memory of the apparatus 102. The memory device 108 may, however, form at least part of a cache memory, a storage memory, or a system-on-chip of the apparatus 102. The memory device 108 includes at least one instance of usage-based disturbance circuitry 120 (UBD circuitry 120) and at least one instance of usage-based-disturbance data repair circuitry 122 (UBD data repair circuitry 122).

The usage-based disturbance circuitry 120 mitigates usage-based disturbance for one or more banks associated with the memory device 108. The usage-based disturbance circuitry 120 can be implemented using software, firmware, hardware, fixed circuit circuitry, or combinations thereof. The usage-based disturbance circuitry 120 can also include at least one counter circuit for detecting conditions associated with usage-based disturbance, at least one queue for managing refresh operations for mitigating the usage-based disturbance, and/or at least one error-correction-code (ECC) circuit for detecting and/or correcting bit errors associated with usage-based disturbance.

One aspect of usage-based disturbance mitigation involves keeping track of how often a row is activated or accessed since a last refresh. In particular, the usage-based disturbance circuitry 120 performs an array counter update procedure using the counter circuit to update an activation count associated with an activated row. During the array counter update procedure, the usage-based disturbance circuitry 120 reads the activation count that is stored within the activated row, increments the activation count, and writes the updated activation count to the activated row. By maintaining the activation count, the usage-based disturbance circuitry 120 can determine when to perform a refresh operation to reduce the risk of usage-based disturbance. For example, when the activation count meets or exceeds a threshold, the usage-based disturbance circuitry 120 can perform a mitigation procedure that refreshes one or more rows that are near the activated row to mitigate the usage-based disturbance.

Generally speaking, the techniques for logging a memory address associated with faulty usage-based-disturbance data can be performed, at least partially, by the usage-based-disturbance data repair circuitry 122. More specifically, these techniques can be implemented using at least one detection circuit 124 and at least one address logging circuit 126. The address logging can be performed at a local-bank level 128 or at a global-bank level 130, as further described below.

The detection circuit 124 detects an occurrence (or absence) of a fault associated with data that is referenced by the usage-based disturbance circuitry 120 to mitigate usage-based disturbance. This data is referred to as usage-based-disturbance data. Generally speaking, the memory device 108 can perform a variety of error detection tests to determine whether or not the usage-based-disturbance data (or memory cells that store the usage-based-disturbance data) is faulty. Example error detection tests include a parity bit check, an error-correcting-code check, a checksum check, a cyclic redundancy check, another type of error detection procedure, or some combination thereof. In some implementations, the detection circuit 124 performs the error detection test and therefore directly detects the fault. In other implementations, the usage-based disturbance circuitry 120 performs the error detection test as part of the array counter update procedure. In this case, the detection circuit 124 stores information about any faults detected by the usage-based disturbance circuitry 120. The detection circuit 124 communicates the occurrence of the detected fault to the address logging circuit 126.

At the global-bank level 130, the address logging circuit 126 logs (or captures) an address associated with the faulty usage-based-disturbance data based on the detection circuit 124 indicating the occurrence of the detected fault. The address logging circuit 126 can further provide the logged address to other components of the memory device 108 so that the occurrence of the fault and the logged address can be communicated to the host device 104.

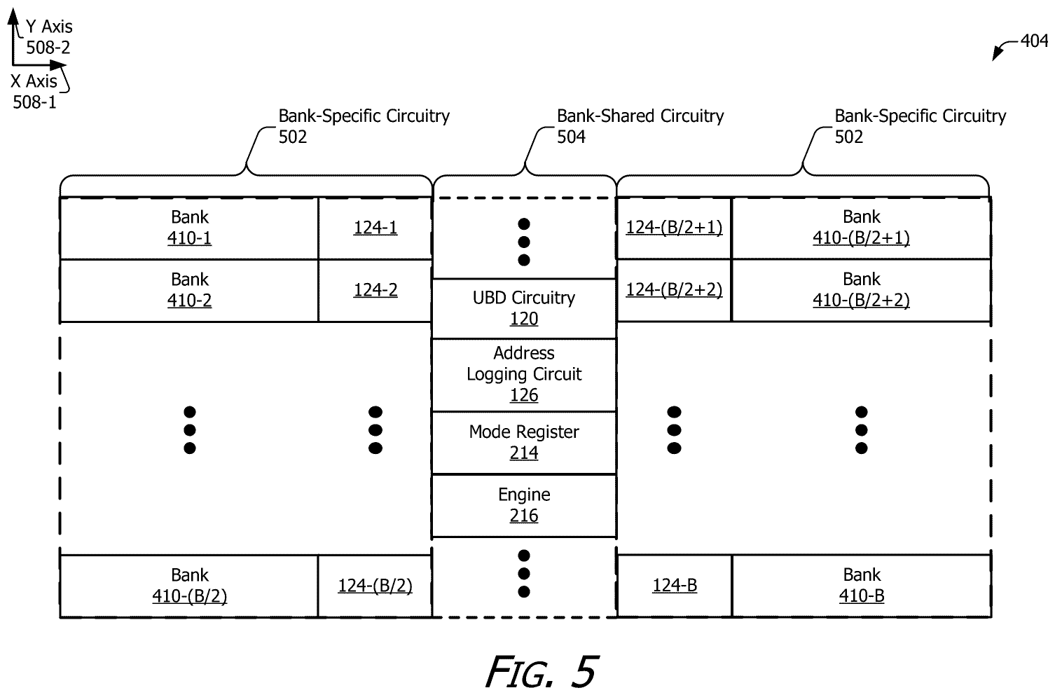

In example implementations, the detection circuit 124 is implemented at the local-bank level 128. This means that each detection circuit 124 detects the occurrence of faults within a corresponding bank of the memory device 108. The address logging circuit 126, in contrast to the detection circuit 124, is implemented at the global-bank level 130. This means that one instance of the address logging circuit 126 can service two or more banks of the memory device 108. At the global-bank level 130, the address logging circuit 126 can readily pass information about the detected fault in a manner that enables the host device 104 to initiate the repair procedure. The local-bank level 128 implementation of the detection circuit 124 and the global-bank level 130 implementation of the address logging circuit 126 are further described with respect to FIG. 5.

The usage-based-disturbance data repair circuitry 122 enables information about the occurrence of the fault and the address associated with the fault to be communicated to or accessed by the host device 104 (e.g., the memory controller 114). With this information, the host device 104 can initiate a repair procedure to fix the faulty data within the memory device 108. One type of repair procedure is a hard post-package repair (hPPR) procedure. For the hard post-package repair procedure, the memory controller 114 can request that the memory device 108 permanently repair a whole combination row, including the faulty data used for usage-based disturbance mitigation. With this repair procedure, however, the viability of existing data stored in the memory row is uncertain. Further, the permanent, nonvolatile nature of the hard post-package repair can entail blowing a fuse. The procedure is relatively lengthy and can often be performed only during power up and initialization, or with a full memory reset, instead of in real-time while the memory device 108 is functional and performing memory operations for the host device 104.

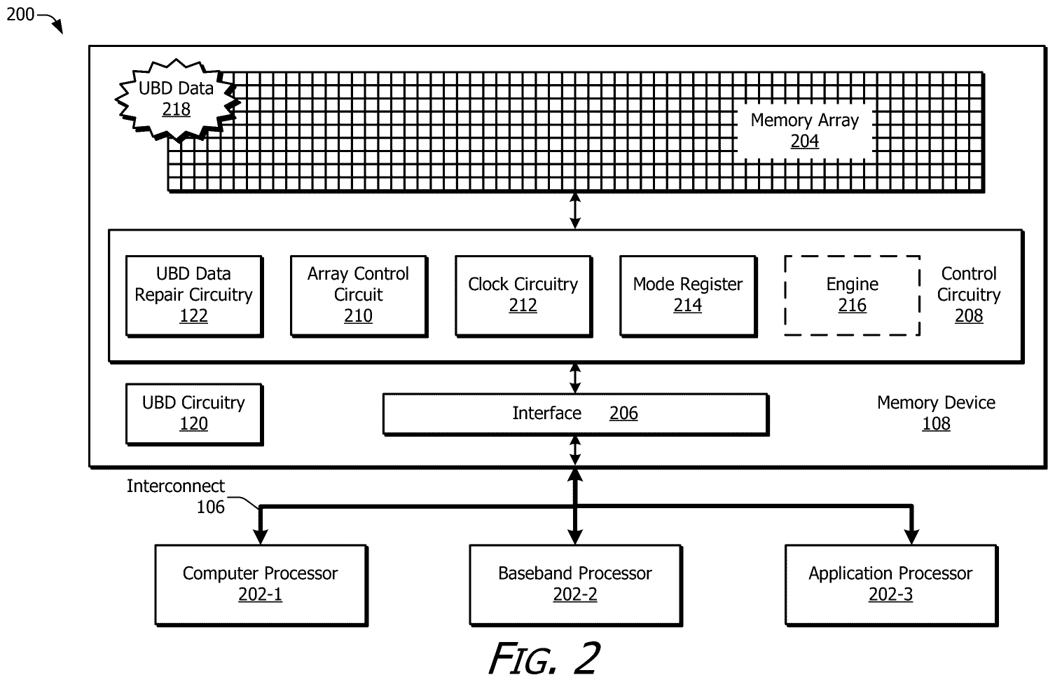

In contrast with the hard post-package repair, a soft post-package repair (sPPR) is a temporary repair procedure that is significantly faster. Further, although a soft post-package repair procedure produces a volatile repair, the soft post-package repair procedure can be performed in real-time responsive to detection of a failure. If a memory row is being repaired, the computing system may be responsible, however, for handling the data transfer (e.g., a full page of data) from the memory row corresponding to the faulty activation count to a spare counter and memory row combination. This data transfer can consume an appreciable amount of time while occupying the data bus. Other components of the memory device 108 are further described with respect to FIG. 2.

FIG. 2 illustrates an example computing system 200 that can implement aspects of logging a memory address associated with faulty usage-based-disturbance data. In some implementations, the computing system 200 includes at least one memory device 108, at least one interconnect 106, and at least one processor 202. The memory device 108 can include, or be associated with, at least one memory array 204, at least one interface 206, and control circuitry 208 (or periphery circuitry) operatively coupled to the memory array 204. The memory array 204 can include an array of memory cells, including but not limited to memory cells of DRAM, SDRAM, three-dimensional (3D) stacked DRAM, DDR memory, LPDDR SDRAM, and so forth. The memory array 204 and the control circuitry 208 may be components on a single semiconductor die or on separate semiconductor dies. The memory array 204 or the control circuitry 208 may also be distributed across multiple dies. This control circuitry 208 may manage traffic on a bus that is separate from the interconnect 106.

The control circuitry 208 can include various components that the memory device 108 can use to perform various operations. These operations can include communicating with other devices, managing memory performance, performing refresh operations (e.g., self-refresh operations or auto-refresh operations), and performing memory read or write operations. In the depicted configuration, the control circuitry 208 includes the usage-based-disturbance data repair circuitry 122, at least one array control circuit 210, at least one instance of clock circuitry 212, and at least one mode register 214. The control circuitry 208 can also optionally include at least one engine 216.

The array control circuit 210 can include circuitry that provides command decoding, address decoding, input/output functions, amplification circuitry, power supply management, power control modes, and other functions. The clock circuitry 212 can synchronize various memory components with one or more external clock signals provided over the interconnect 106, including a command-and-address clock or a data clock. The clock circuitry 212 can also use an internal clock signal to synchronize memory components and may provide timer functionality.

In general, the control circuitry 208 stores the addresses that are logged by the usage-based-disturbance data repair circuitry 122 in a manner that can be accessed by the memory controller 114. With this information, the memory controller 114 can initiate an appropriate repair procedure. In an example implementation, the mode register 214 facilitates control by and/or communication with the memory controller 114 (or one of the processors 202). Using the mode register 214, the memory device 108 can communicate information to the memory controller 114. Such communications can cause entry into or exit from a repair mode or a command that provides a memory row address to target for a repair procedure. To facilitate this communication, the mode register 214 may include one or more registers having at least one bit relating to usage-based disturbance repair functionality.

When implemented and enabled, the engine 216 can access each row of the memory array 204 in a controlled manner. The manner in which the engine 216 accesses the rows of the memory array 204 can be in accordance with an automatic mode or a manual mode. Generally, given sufficient time, the engine 216 accesses all rows of the memory array 204. In some implementations, the engine 216 accesses the rows of the memory array 204 in a periodic or cyclic manner. An order in which the engine 216 access the rows can be a predetermined order, a rule-based order, or a randomized order. In some implementations, the engine 216 is implemented as a test engine, which can detect and/or correct errors within at least a subset of the data that is stored within the rows. Example engines include an error-check and scrub engine (ECS engine), an add-based engine, or a refresh engine.

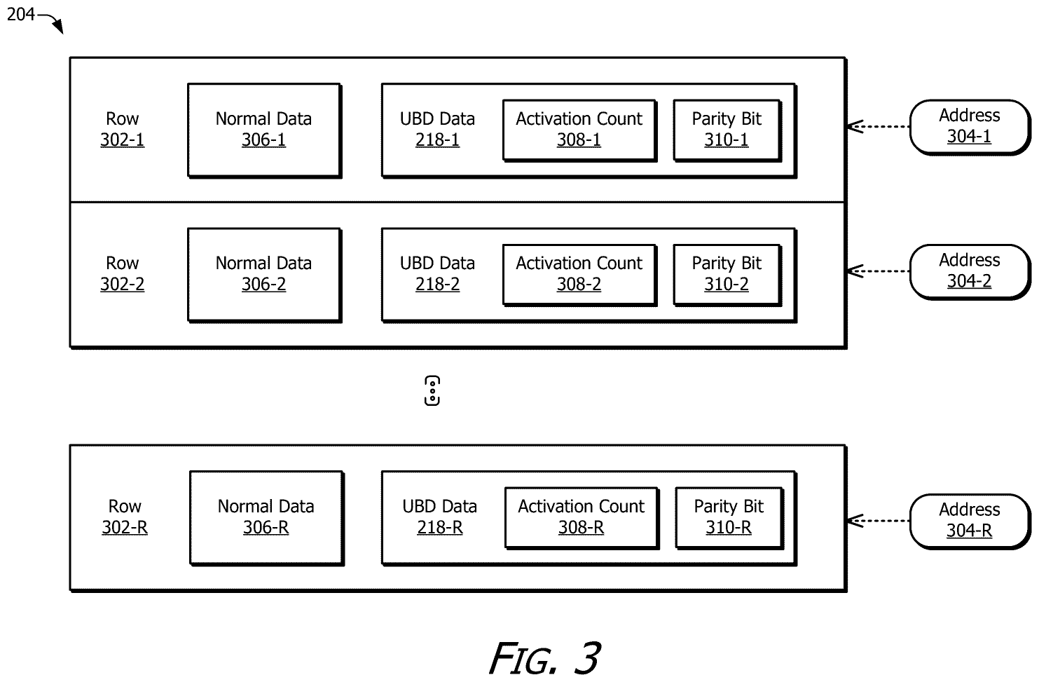

The memory device 108 also includes the usage-based disturbance circuitry 120. In some aspects, the usage-based disturbance circuitry 120 can be considered part of the control circuitry 208. For example, the usage-based disturbance circuitry 120 can represent another part of the control circuitry 208. The usage-based disturbance circuitry 120 can be coupled to a set of memory cells within the memory array 204 that store usage-based-disturbance data 218 (UBD data 218). The usage-based-disturbance data 218 can include information such as an activation count, which represents a quantity of times one or more rows within the memory array 204 have been activated (or accessed) by the memory device 108. In example implementations, each row of the memory array 204 includes a subset of memory cells that stores the usage-based-disturbance data 218 associated with that row, as further described with respect to FIG. 3.

The interface 206 can couple the control circuitry 208 or the memory array 204 directly or indirectly to the interconnect 106. In some implementations, the usage-based disturbance circuitry 120, the usage-based-disturbance data repair circuitry 122, the array control circuit 210, the clock circuitry 212, the mode register 214, and the engine 216 can be part of a single component (e.g., the control circuitry 208). In other implementations, one or more of the usage-based disturbance circuitry 120, the usage-based-disturbance data repair circuitry 122, the array control circuit 210, the clock circuitry 212, the mode register 214, or the engine 216 may be implemented as separate components, which can be provided on a single semiconductor die or disposed across multiple semiconductor dies. These components may individually or jointly couple to the interconnect 106 via the interface 206.

The interconnect 106 may use one or more of a variety of interconnects that communicatively couple together various components and enable commands, addresses, or other information and data to be transferred between two or more components (e.g., between the memory device 108 and the processor 202). Although the interconnect 106 is illustrated with a single line in FIG. 2, the interconnect 106 may include at least one bus, at least one switching fabric, one or more wires or traces that carry voltage or current signals, at least one switch, one or more buffers, and so forth. Further, the interconnect 106 may be separated into at least a command-and-address bus and a data bus.

In some aspects, the memory device 108 may be a “separate” component relative to the host device 104 (of FIG. 1) or any of the processors 202. The separate components can include a printed circuit board, memory card, memory stick, and memory module (e.g., a single in-line memory module (SIMM) or dual in-line memory module (DIMM)). Thus, separate physical components may be located together within the same housing of an electronic device or may be distributed over a server rack, a data center, and so forth. Alternatively, the memory device 108 may be integrated with other physical components, including the host device 104 or the processor 202, by being combined on a printed circuit board or in a single package or a system-on-chip.

As shown in FIG. 2, the processors 202 may include a computer processor 202-1, a baseband processor 202-2, and an application processor 202-3, coupled to the memory device 108 through the interconnect 106. The processors 202 may include or form a part of a central processing unit, graphics processing unit, system-on-chip, application-specific integrated circuit, or field-programmable gate array. In some cases, a single processor can comprise multiple processing resources, each dedicated to different functions (e.g., modem management, applications, graphics, central processing). In some implementations, the baseband processor 202-2 may include or be coupled to a modem (not illustrated in FIG. 2) and referred to as a modem processor. The modem or the baseband processor 202-2 may be coupled wirelessly to a network via, for example, cellular, Wi-Fi®, Bluetooth®, near field, or another technology or protocol for wireless communication.

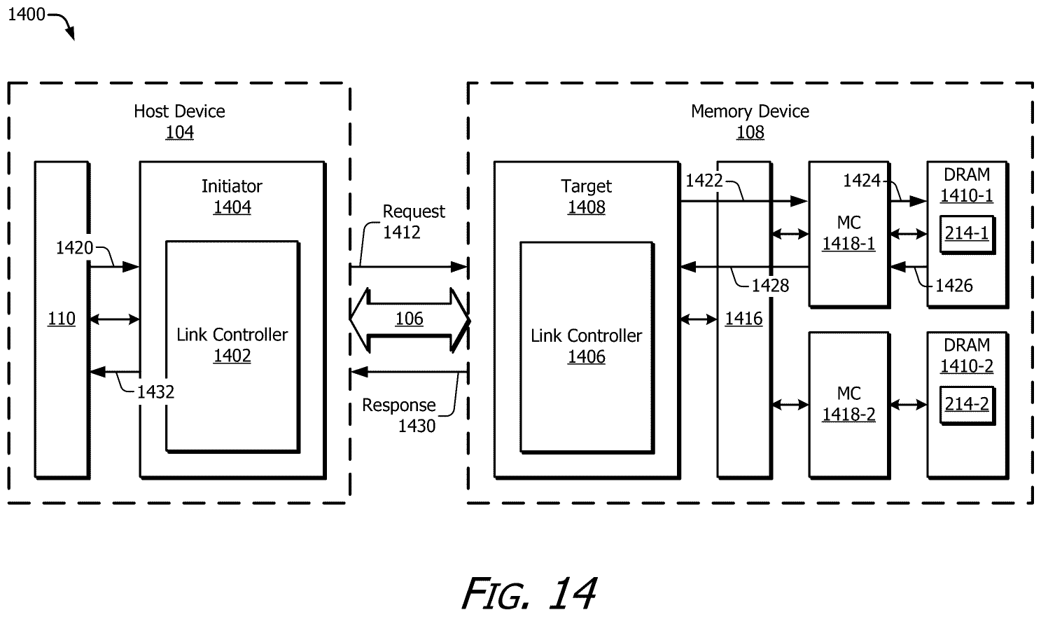

In some implementations, the processors 202 may be connected directly to the memory device 108 (e.g., via the interconnect 106). In other implementations, one or more of the processors 202 may be indirectly connected to the memory device 108 (e.g., over a network connection or through one or more other devices). Further, the processor 202 may be realized as one that can communicate over a CXL-compatible interconnect. Accordingly, a respective processor 202 can include or be associated with a respective link controller, like the link controller illustrated in FIG. 14. Alternatively, two or more processors 202 may access the memory device 108 using a shared link controller. In some of such cases, the memory device 108 may be implemented as a CXL-compatible memory device (e.g., as a CXL Type 3 memory expander) or another memory device that is compatible with a CXL protocol may also or instead be coupled to the interconnect 106. The memory array 204 is further described with respect to FIG. 3.

FIG. 3 illustrates example data stored within rows of the memory array 204. The memory array 204 includes multiple rows 302 of memory cells. For example, the memory array 204 depicted in FIG. 3 includes rows 302-1, 302-2 . . . 302-R, where R represents a positive integer. Each row 302 is associated with an address 304 (e.g., a row address, a memory row address, or a memory address). For example, the first row 302-1 has a first address 304-1, the second row 302-2 has a second address 304-2, and an R^{th} row 302-R has an R^{th} address 304-R.

Each of the rows 302 can store normal data 306 within a first subset of the memory cells associated with that row 302. The normal data 306 represents data that is read from or written to the memory device 108 during normal memory operations (e.g., during normal read or write operations). The normal data 306, for example, can include data that is transmitted by the memory controller 114 and is written to one or more rows 302 of the memory array 204.

In addition to the normal data 306, each of the rows 302 can store usage-based-disturbance data 218 within a second subset of the memory cells associated with that row 302. The usage-based-disturbance data 218 includes information that enables the usage-based disturbance circuitry 120 to mitigate usage-based disturbance. In an example implementation, the usage-based-disturbance data 218 includes an activation count 308.

In this example, the first row 302-1 stores first normal data 306-1 within a first subset of memory cells of the first row 302-1 and stores first usage-based-disturbance data 218-1 within a second subset of memory cells of the first row 302-1. The first usage-based-disturbance data 218-1 includes a first activation count 308-1, which represents a quantity of times the first row 302-1 has been activated since a last refresh. As another example, the second row 302-2 stores second normal data 306-2 within a first subset of memory cells within the second row 302-2 and stores second usage-based-disturbance data 218-2 within a second subset of memory cells within the second row 302-2. The second usage-based-disturbance data 218-2 includes a second activation count 308-2, which represents a quantity of times the second row 302-2 has been activated since a last refresh. Additionally, the R^{th} row 302-R stores R^{th} normal data 306-R within a first subset of memory cells within the R^{th} row 302-R and stores R^{th} usage-based-disturbance data 218-R within a second subset of memory cells within the R^{th} row 302-R. The R^{th} usage-based-disturbance data 218-R includes an R^{th} activation count 308-R, which represents a quantity of times the R^{th} row 302-R has been activated since a last refresh.

The usage-based-disturbance data 218 also includes information or is formatted (e.g., coded) in such a way as to support error detection. In this example, the usage-based-disturbance data 218 includes a parity bit 310 to enable detection of a faulty activation count 308 using a parity check. For instance, the usage-based-disturbance data 218-1, 218-2, and 218-R respectively includes parity bits 310-1, 310-2, and 310-R. Other implementations are also possible in which the usage-based-disturbance data 218 is coded in a manner that supports any of the error detection tests described above, such as the error-correcting-code check. Although the techniques for logging a memory address associated with faulty usage-based-disturbance data 218 are described with respect to parity-bit errors associated with the activation count 308, these techniques can generally be applied for logging addresses for any type of usage-based-disturbance data 218 and any type of error detection associated with this data.

### Example Techniques and Hardware

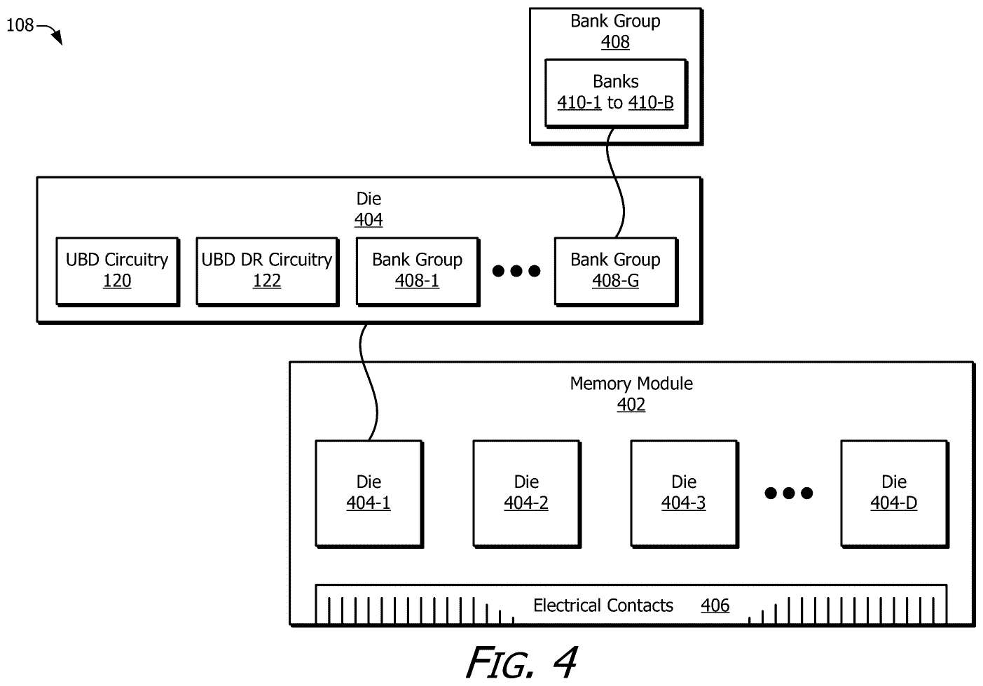

FIG. 4 illustrates an example memory device 108 in which aspects of logging a memory address associated with faulty usage-based-disturbance data can be implemented. The memory device 108 includes a memory module 402, which can include multiple dies 404. As illustrated, the memory module 402 includes a first die 404-1, a second die 404-2, a third die 404-3, and a D^{th} die 404-D, with D representing a positive integer. The memory module 402 can be a SIMM or a DIMM. As another example, the memory module 402 can interface with other components via a bus interconnect (e.g., a Peripheral Component Interconnect Express (PCIe®) bus). The memory device 108 illustrated in FIGS. 1 and 2 can correspond, for example, to multiple dies (or dice) 404-1 through 404-D, or a memory module 402 with two or more dies 404. As shown, the memory module 402 can include one or more electrical contacts 406 (e.g., pins) to interface the memory module 402 to other components.

The memory module 402 can be implemented in various manners. For example, the memory module 402 may include a printed circuit board, and the multiple dies 404-1 through 404-D may be mounted or otherwise attached to the printed circuit board. The dies 404 (e.g., memory dies) may be arranged in a line or along two or more dimensions (e.g., forming a grid or array). The dies 404 may have a similar size or may have different sizes. Each die 404 may be similar to another die 404 or different in size, shape, data capacity, or control circuitries. The dies 404 may also be positioned on a single side or on multiple sides of the memory module 402.

One or more of the dies 404-1 to 404-D include the usage-based disturbance circuitry 120, the usage-based-disturbance data repair circuitry 122 (UBD DR circuitry 122), and bank groups 408-1 to 408-G, with G representing a positive integer. Each bank group 408 includes at least two banks 410, such as banks 410-1 to 410-B, with B representing a positive integer. In some implementations, the die 404 includes multiple instances of the usage-based disturbance circuitry 120, which mitigate usage-based disturbance across at least one of the banks 410. For example, multiple instances of the usage-based disturbance circuitry 120 can respectively mitigate usage-based disturbance across the bank groups 408-1 to 408-G. In this example, one instance of usage-based disturbance circuitry 120 mitigates usage-based disturbance across multiple banks 410-1 to 410-B of a bank group 408. In another example, multiple instances of the usage-based disturbance circuitry 120 can respectively mitigate usage-based disturbance for respective banks 410. In this case, each usage-based disturbance circuitry 120 mitigates usage-based disturbance for a single bank 410 within one of the bank groups 408-1 to 406-B. In yet another example, each usage-based disturbance circuitry 120 mitigates usage-based disturbance for a subset of the banks 410 associated with one of the bank groups 408-1 to 408-G, where the subset of the banks 410 includes at least two banks 410. The relationship between the banks 410-1 to 410-B and components of the usage-based-disturbance data repair circuitry 122 are further described with respect to FIG. 5.

FIG. 5 illustrates an example arrangement of multiple detection circuits 124 and the address logging circuit 126 on a die 404. The die 404 includes bank-specific circuitry 502 and bank-shared circuitry 504. Bank-specific circuitry 502 includes components that are associated with a particular bank 410. For example, the bank-specific circuitry 502 includes the banks 410-1, 410-2 . . . 410-(B/2), 410-(B/2+1), 410-(B/2+2) . . . 410-B and the detection circuits 124-1, 124-2 . . . 124-(B/2), 124-(B/2+1), 124-(B/2+2) . . . 124-B. The detection circuits 124-1 to 124-B are respectively coupled to the banks 410-1 to 410-B. In some cases, subsets of the banks 410-1 to 410-B are associated with different bank groups 408. In an example implementation, the die 404 includes 32 banks 410 (e.g., B equals 32). The 32 banks 410 form eight bank groups 408 (e.g., G equals 8), with each bank group 408 including four of the banks 410. In other cases, the banks 410-1 to 410-B are associated with a single bank group 408.

Each detection circuit 124 can detect occurrence of a fault (or an error) associated with the usage-based-disturbance data 218 stored within the corresponding bank 410. For example, the first detection circuit 124-1 can monitor for faults associated with the usage-based-disturbance data 218 stored within the rows 302 of the first bank 410-1. Likewise, the second detection circuit 124-2 can monitor for faults associated with the usage-based-disturbance data 218 stored within the rows 302 of the second bank 410-2.

The bank-shared circuitry 504 includes components that are associated with multiple banks 410. These components perform operations associated with multiple banks 410. Example components of the bank-shared circuitry 504 include the address logging circuit 126, the mode register 214, and the engine 216 (if implemented). In this example, the usage-based disturbance circuitry 120 is also shown as part of the bank-shared circuitry 504. Alternatively, multiple instances of the usage-based disturbance circuitry 120 can be implemented as part of the bank-specific circuitry 502. In an example implementation, the address logging circuit 126 is positioned proximate to the engine 216 and the mode register 214.

On the die 404, the bank-specific circuitry 502 is positioned on two opposite sides of the bank-shared circuitry 504. Explained another way, the bank-shared circuitry 504 can be centrally positioned on the die 404. As such, the address logging circuit 126 can be positioned closer to a center of the die 404 compared to the edges of the die 404. Positioning the bank-shared circuitry 504 in the center enables routing between the bank-shared circuitry 504 and the bank-specific circuitry 502 to be simplified.

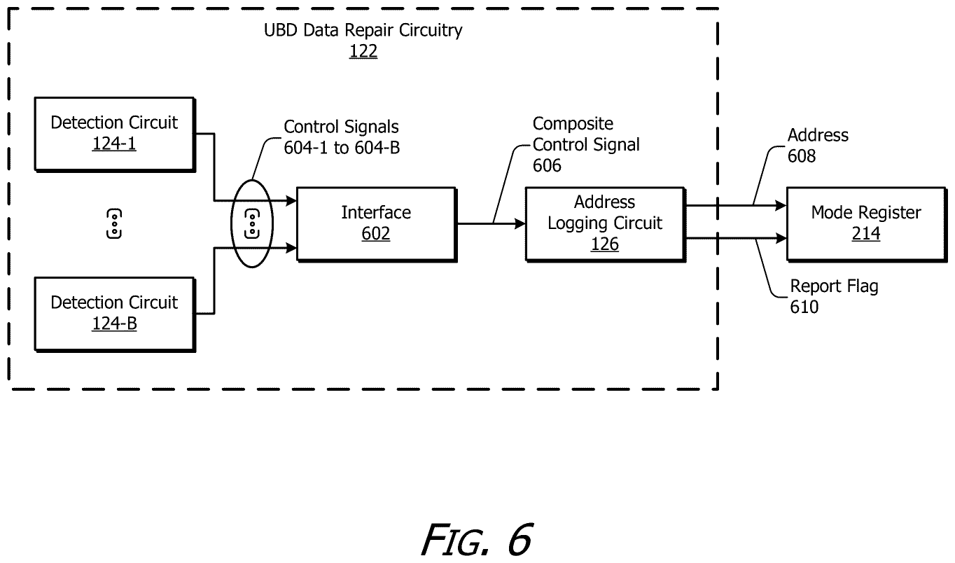

Consider a first axis 508-1 (e.g., X axis 508-1) and a second axis 508-2 (e.g., Y axis 508-2), which is perpendicular to the first axis 508-1. In FIG. 5, the first axis 508-1 is depicted as a “horizontal” axis, and the second axis 508-2 is depicted as a “vertical” axis. Components of the bank-shared circuitry 504 are distributed across the second axis 508-2. A first set of the banks (e.g., banks 410-1 to 410-B/2) are arranged along the second axis 508-2 on a “left” side of the bank-shared circuitry 504, and a second set of the banks (e.g., banks 410-(B/2+1) to 410-B) are arranged along the second axis 508-2 on a “right” side of the bank-shared circuitry 504. The detection circuits 124-1 to 124-B are positioned between the corresponding banks 410-1 to 410-B and the bank-shared circuitry 504. By positioning the address logging circuit 126 in a central location between the detection circuits 124-1 to 124-B, it can be easier to route signals between the address logging circuit 126 and the detection circuits 124-1 to 124-B. Operations of the detection circuits 124 and the address logging circuit 126 are further described with respect to FIG. 6.

FIG. 6 illustrates an example of the usage-based-disturbance data repair circuitry 122 coupled to the mode register 214. Although the mode register 214 is depicted as a single register in FIG. 6, other implementations of the mode register 214 can include more than one mode register.

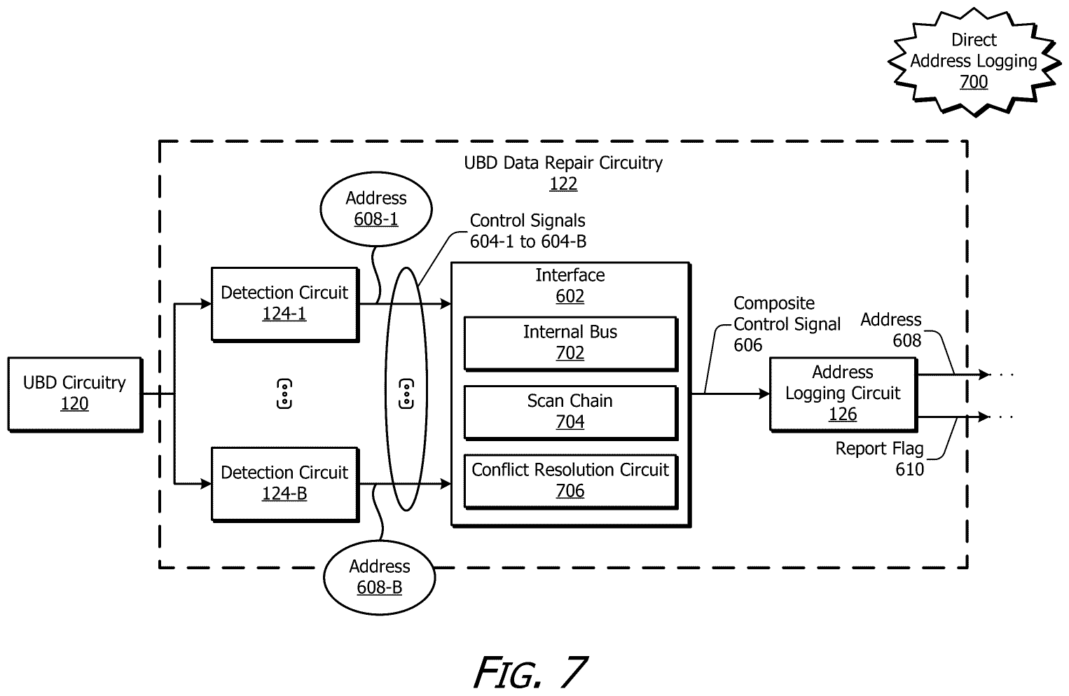

In the depicted configuration, the usage-based-disturbance data repair circuitry 122 includes the detection circuits 124-1 to 124-B and the address logging circuit 126, which is coupled to the mode register 214. Although not explicitly shown in FIG. 6, the detection circuits 124 and/or the address logging circuit 126 can be coupled to other components of the memory device, examples of which are described with respect to FIGS. 7 to 11.

The usage-based-disturbance data repair circuitry 122 also includes an interface 602, which is coupled between the detection circuits 124-1 to 124-B and the address logging circuit 126. In general, the interface 602 provides a means for communication between a component at the local-bank level 128 (e.g., one of the detection circuits 124-1 to 124-B) and a component at the global-bank level 130 (e.g., the address logging circuit 126). Various implementations of the interface 602 are further described with respect to FIGS. 7 to 11.

During operation, the detection circuits 124-1 to 124-B respectively generate control signals 604-1 to 604-B. The control signals 604-1 to 604-B at least indicate whether or not the respective detection circuits 124-1 to 124-B detect an occurrence of faulty usage-based-disturbance data 218 within the corresponding banks 410-1 to 410-B.

The interface 602 generates a composite control signal 606 based on the control signals 604-1 to 604-B. The composite control signal 606 represents some combination of the local-bank address logging control signals 604-1 to 604-B. Using the composite control signal 606, the interface 602 can pass information provided by any one of the control signals 604-1 to 604-B to the address logging circuit 126.

The address logging circuit 126 can provide an address 608 and/or a report flag 610 to the mode register 214 based on the composite control signal 606. The address 608 represents at least one of the addresses 304 for which the detection circuits 124-1 to 124-B determined is associated with the faulty usage-based-disturbance data 218. The report flag 610 indicates whether or not faulty usage-based-disturbance data 218 has been detected. In one example implementation, the report flag 610 represents a flag that is dedicated for detecting faults (or errors) associated with the usage-based-disturbance data 218. In another example implementation, the report flag 610 is implemented using another flag or signal that already exists within the memory device 108. For example, the report flag 610 can be implemented using the reliability, availability, and serviceability (RAS) event signal or another alert signal. The report flag 610 can also be referred to as an error flag, a parity flag, an activation count error flag, an activation count parity flag, and so forth. In some cases, the report flag 610 can indicate that the address 608 is stored by the mode register 214.

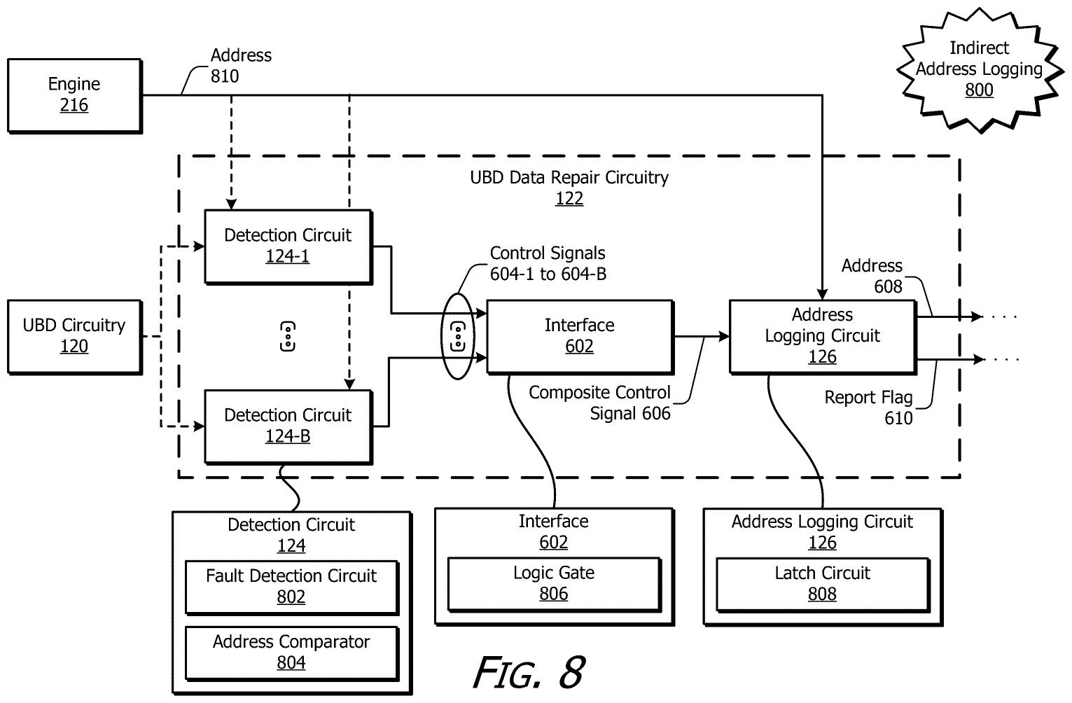

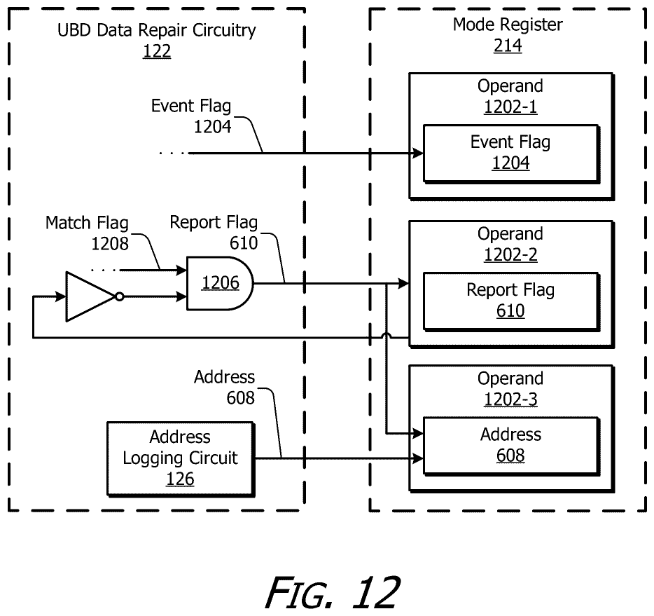

The mode register 214 stores the address 608 and/or the report flag 610. In some cases, the mode register 214 includes two registers that respectively store the address 608 and the report flag 610. In another case, the mode register 214 includes one register that stores both the address 608 and the report flag 610. An example implementation of the mode register 214 is further described with respect to FIG. 12. The memory controller 114 can initiate one or more repair procedures based on the address 608 and/or the report flag 610 stored by the mode register 214. In some implementations, the memory controller 114 can clear the report flag 610 upon initiating a repair procedure. The usage-based-disturbance data repair circuitry 122 can perform aspects of direct or indirect address logging, as further described with respect to FIGS. 7 and 8, respectively.

FIG. 7 illustrates an example implementation of the usage-based-disturbance data repair circuitry 122, which directly performs address logging at the local-bank level 128 as indicated at 700. In the depicted configuration, the control signals 604 indicate the address 608 associated with the faulty usage-based-disturbance data 218. In this example, the usage-based-disturbance data repair circuitry 122 can be coupled to the usage-based disturbance circuitry 120. This coupling enables the detection circuits 124-1 to 124-B to operate during the array counter update procedure, as further described below.

To communicate the address 608 from the local-bank level 128 to the global-bank level 130, the interface 602 can be implemented using at least on internal bus 702 or at least one scan chain 704. The interface 602 can also include a conflict resolution circuit 706, which can resolve conflicts in which at least two detection circuits 124 detect an occurrence of faulty usage-based-disturbance data 218 during a same time interval.

During operation, the usage-based disturbance circuitry 120 performs the array counter update procedure on an active row. As part of the array counter update procedure, the usage-based disturbance circuitry 120 or the detection circuits 124-1 to 124-B perform an error detection test to detect a fault associated with the usage-based-disturbance data 218 (e.g., perform a parity check to detect a parity-bit failure associated with the activation count 308). If a fault is detected, the detection circuit 124 associated with the bank 410 in which the fault occurs determines the address 608 associated with the detected fault. For example, the detection circuit 124-1 determines that the address 608-1 is associated with the fault and/or the detection circuit 124-B determines that the address 608-B is associated with the fault. The detection circuits 124-1 to 124-B communicate the addresses 608-1 to 608-B to the address logging circuit 126 using the control signals 604-1 to 604-B.

While direct address logging 700 enables the address 608 associated with the faulty usage-based-disturbance data 218 to be logged during the array counter update procedure and enables this address 608 to be stored in the mode register 214 with minimal delay, direct address logging 700 can increase a complexity and/or layout penalty associated with implementing the interface 602. This can increase the cost and/or size of the memory device 108. Alternatively, other implementations of the usage-based-disturbance data repair circuitry 122 can perform indirect address logging, which is further described with respect to FIG. 8.

FIG. 8 illustrates an example implementation of the usage-based-disturbance data repair circuitry 122, which indirectly performs address logging at the global-bank level 130, as indicated at 800, with the assistance of the engine 216. The engine 216 can be an existing engine 216 within the memory device 108 that performs other functions not associated with usage-based disturbance mitigation. In this case, the engine 216 accesses the rows 302 within the memory array 204 in a controlled manner or in a particular sequence. The information provided by the detection circuits 124-1 to 124-B via the control signals 604-1 to 604-B is based on or dependent upon the row 302 being accessed by the engine 216. More specifically, the detection circuits 124-1 to 124-B report faults using the control signals 604-1 to 604-B if the address 608 associated with the fault is related to the row 302 that is accessed by the engine 216. This dependency enables the address logging circuit 126 to determine the address 608 of the fault at the global-bank level 130 based on the row 302 that is accessed by the engine 216 without having the address 608 routed from the local-bank level 128 to the global-bank level 130. This controlled manner also avoids conflicts that can otherwise arise if multiple faults occur across multiple banks 410 during a same time interval. Generally speaking, indirect address logging 800 utilizes the engine 216 to provide a controlled way of logging addresses of faulty usage-based-disturbance data 218 at the global-bank level 130.

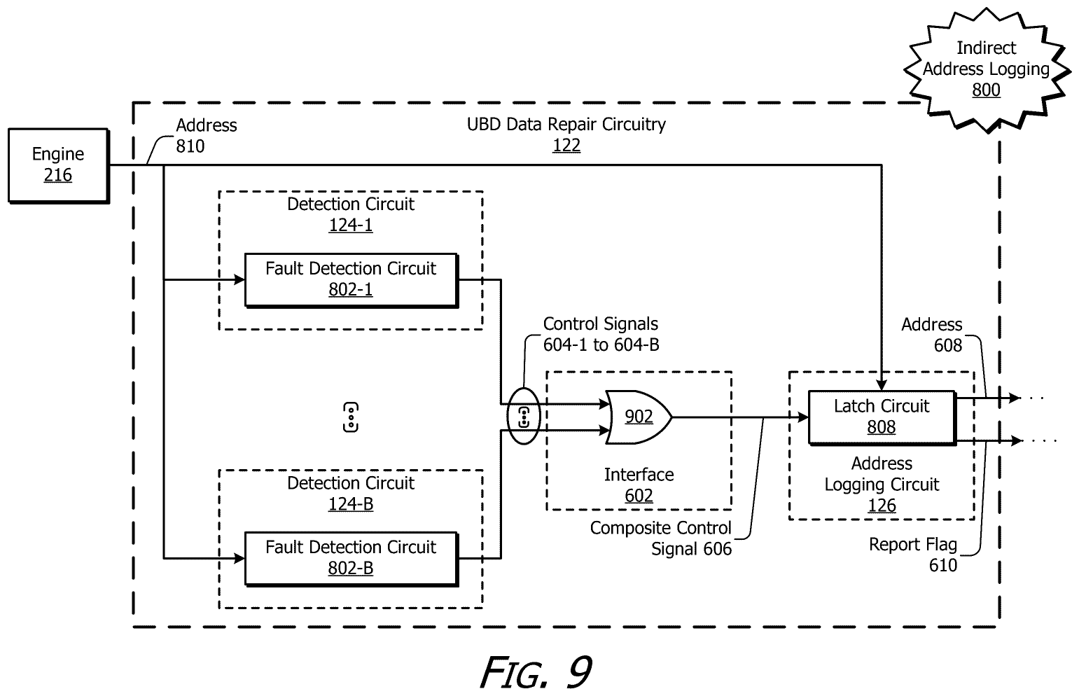

In the depicted configuration, the address logging circuit 126 is coupled to the engine 216. Depending on the implementation, the detection circuits 124-1 to 124-B can be coupled to the usage-based disturbance circuitry 120, the engine 216, or both. Example implementations of the detection circuit 124 can include at least one fault detection circuit 802 and/or at lead one address comparator 804. The interface 602 can include at least one logic gate 806. The logic gate 806 can be implemented at the local-bank level 128 and generates the composite control signal 606 based on the control signals 604-1 to 604-B. The address logging circuit 126 can include at least one latch circuit 808, which can latch information provided by the engine 216 based on the composite control signal 606. Example implementations of the detection circuit 124, the interface 602, and the address logging circuit 126 are further described with respect to FIGS. 9 to 11.

During operation, the engine 216 performs operations on the rows 302 of the memory array 204. The engine 216 controls or determines the sequence in which the rows 302 are accessed. The address logging circuit 126 is coupled to the engine 216 and receives information about an address 810 that is accessed by the engine 216. The address logging circuitry 126 can latch the address 810 at the global-bank level 130 based on the composite control signal 606 indicating occurrence of a fault.

The detection circuits 124-1 to 124-B can determine the occurrence of the fault in different manners. In a first example implementation, the detection circuits 124-1 to 124-B perform the error detection test based on an occurrence of the engine 216 accessing the address 810. In this case, the error detection test is performed on rows 302 in a same order that the engine 216 accesses the rows 302. In a second example implementation, the error detection test is performed by the usage-based disturbance circuitry 120 or the detection circuits 124-1 to 124-B as part of or based on an occurrence of the array counter update procedure (or more generally a procedure that updates the usage-based-disturbance data 218). The detection circuits 124-1 to 124-B store information associated with a detected fault and provide this information if the address 608 of the detected fault matches the address 810 that is accessed by the engine 216. The first example implementation of the detection circuits 124-1 to 124-B is further described with respect to FIG. 9.

FIG. 9 illustrates first example implementations of the detection circuits 124-1 to 124-B for indirect address logging 800. In the depicted configuration, the interface 602 is implemented using a logic gate 806, which is depicted as an OR gate 902. Inputs of the OR gate 902 are coupled to outputs of the detection circuits 124-1 to 124-B. The address logging circuit 126 includes the latch circuit 808, which is coupled to the interface 602 and the engine 216.

The detection circuits 124-1 to 124-B respectively include fault detection circuits 802-1 to 802-B. The fault detection circuits 802-1 to 802-B are coupled to the engine 216 and perform the error detection test to detect faulty usage-based-disturbance data 218. A manner in which the error detection tests are performed across the rows 302, however, is dependent upon a manner in which the engine 216 accesses the rows 302, as further described below.

During operation, the engine 216 performs an operation at a particular row 302. The address 810 that is accessed by the engine 216 is provided to the detection circuits 124-1 to 124-B. If the address 810 is within a bank 410 that corresponds with the detection circuit 124, that detection circuit 124 performs the error detection test on the usage-based-disturbance data 218 associated with the address 810. For example, the detection circuit 124 performs a parity check to evaluate a parity bit 310 associated with the activation count 308. If the address 810 is not within the bank 410 that corresponds with the detection circuit 124, that detection circuit 124 does not perform an error detection test.

If the detection circuit 124 determines that the usage-based-disturbance data 218 associated with the address 810 is faulty, the detection circuit 124 indicates detection of this fault via the corresponding control signal 604. The interface 602 generates the composite control signal 606, which also indicates the detection of the fault. Based on the composite control signal 606 indicating detection of the fault, the latch circuit 808 latches the address 810 that is provided by the engine 216. The address logging circuit 126 provides the address 810 as the address 608 to the mode register 214 (not shown). In some cases, the address logging circuit 126 provides the composite control signal 606, or a portion thereof (e.g., the report flag 610), to the mode register 214, as further described with respect to FIG. 12.

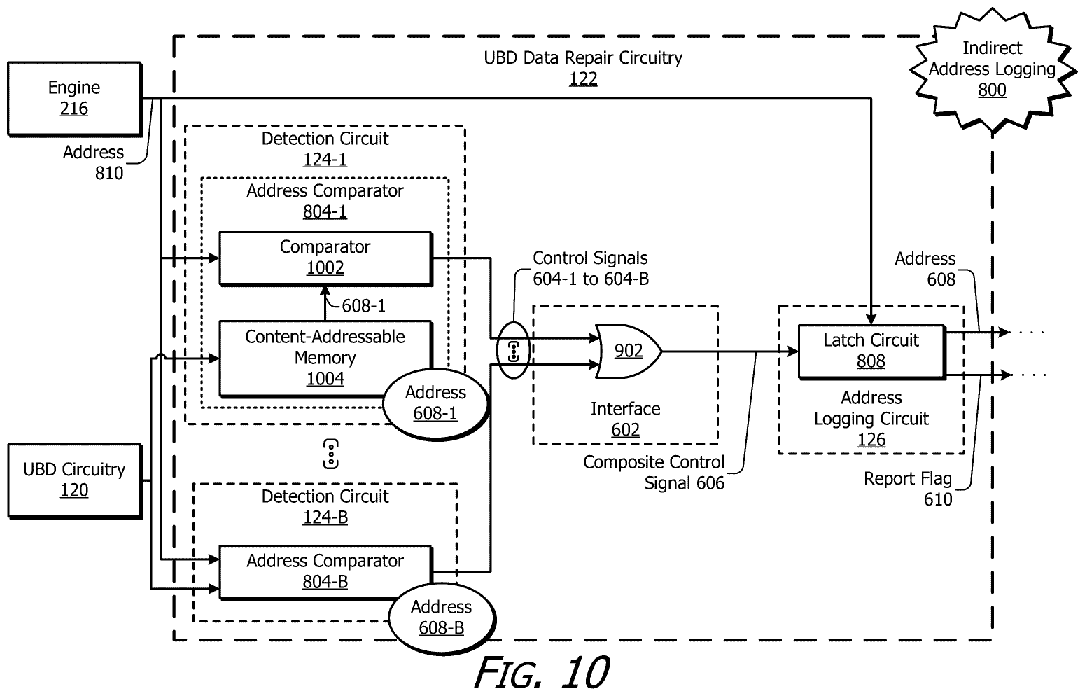

In this example, the execution of the error detection test occurs during or after a time interval in which the engine 216 accesses the address 810. In this manner, the fault detection and address logging are synchronized across the local-bank level 128 and the global-bank level 130 based on the address 810 that is accessed by the engine 216. In other implementations, the fault detection can occur before the engine 216 accesses the address 810, as further described with respect to FIG. 10.

FIG. 10 illustrates second example implementations of the detection circuits 124-1 to 124-B for indirect address logging 800. In the depicted configuration, the detection circuits 124-1 to 124-B respectively include address comparators 804-1 to 804-B. The address comparators 804-1 to 804-B are coupled to the engine 216 and the usage-based disturbance circuitry 120. The address comparators 804-1 to 804-B can each include at least one comparator 1002 and at least one content-addressable memory (CAM) 1004. The comparator 1002 enables the results of the error detection tests to be reported is a manner that is dependent upon a manner in which the engine 216 accesses the rows 302, as further described below. The content-addressable memory 1004 stores information regarding the faulty usage-based-disturbance data 218. In some implementations, the content-addressable memory 1004 can store one address 608 that is determined to have the faulty usage-based-disturbance data 218. In other implementations, the content-addressable memory 1004 can store multiple addresses 608 that are determined to have the faulty usage-based-disturbance data 218.

During operation, the usage-based disturbance circuitry 120 performs the array counter update procedure. As part of the array counter update procedure or based on the occurrence of the array counter update procedure, the usage-based disturbance circuitry 120 or the detection circuits 124-1 to 124-B perform the error detection test to detect faulty usage-based-disturbance data 218. If faulty usage-based-disturbance data 218 is detected, the address 608 of the faulty usage-based-disturbance data 218 is stored within the content-addressable memory 1004 of the address comparator 804.

After the array counter update procedure is performed, the engine 216 accesses the address 810. The comparators 1002 of the address comparators 804-1 to 804-B compare the address 810 to the addresses 608-1 to 608-B stored in the content-addressable memory 1004. Consider an example in which the address 810 is the address 608-1 stored by the address comparator 804-1. In this case, the comparator 1002 of the detection circuit 124-1 determines that the address 810 matches the address 608-1, and generates the control signal 604-1 in a manner that indicates detection of faulty usage-based-disturbance data 218. The interface 602 generates the composite control signal 606, which also indicates the detection of the fault. Based on the composite control signal 606 indicating detection of the fault, the latch circuit 808 latches the address 810 that is provided by the engine 216. The address logging circuit 126 provides the address 810 as the address 608 to the mode register 214 (not shown). In some cases, the address logging circuit 126 provides the composite control signal 606 as the report flag 610.

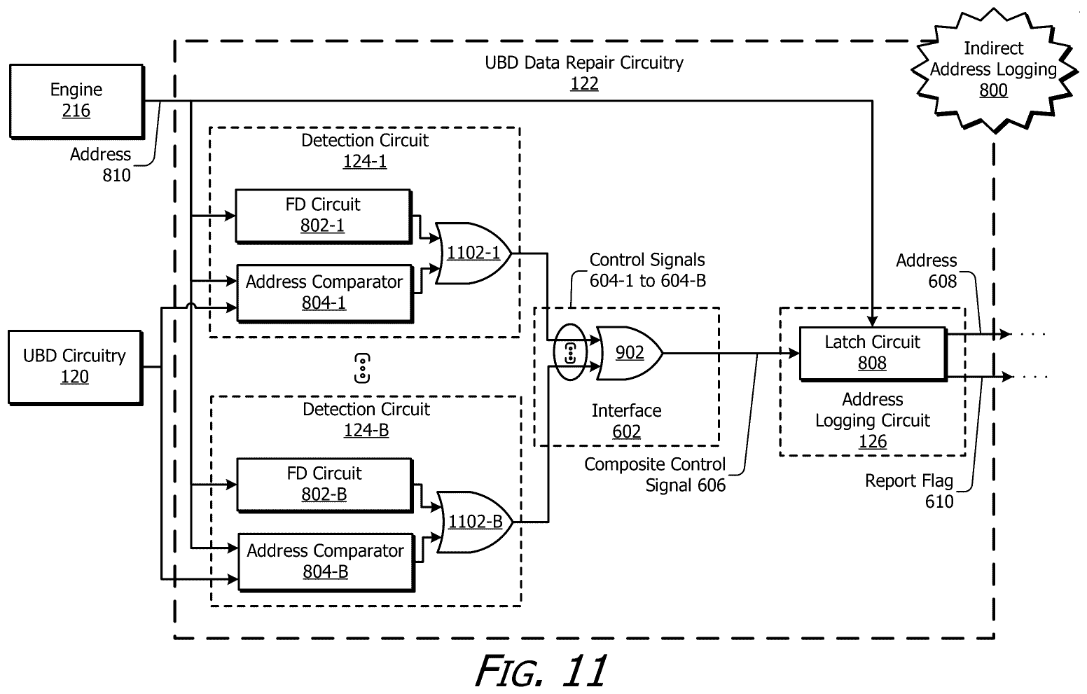

In this example, the execution of the error detection test occurs before a time interval in which the engine 216 accesses the address 810. Although the fault detection and address logging can occur at different time intervals, reporting of the fault detection and address logging are synchronized across the local-bank level 128 and the global-bank level 130 based on the address 810 that is accessed by the engine 216. In still other implementations, the detection circuits 124-1 to 124-B can include both the fault detection circuits 802 and the address comparators 804, as further described with respect to FIG. 11.

FIG. 11 illustrates third example implementations of the detection circuits 124-1 to 124-B. In the depicted configuration, the detection circuits 124-1 to 124-B respectively include the fault detection circuits 802-1 to 802-B, the address comparators 804-1 to 804-B, and optionally the OR gates 1102-1 to 1102-B. The operations of the fault detection circuits 802-1 to 802-B are similar to the operations described with respect to FIG. 9. The operations of the address comparators 804-1 to 804-B are similar to the operations described with respect to FIG. 10.

This implementation of the detection circuits 124-1 to 124-B provides additional opportunities for the error detection tests to be executed, and therefore enables the usage-based-disturbance data repair circuitry 122 to more quickly detect faulty usage-based-disturbance data 218. For example, the fault detection circuits 802-1 to 802-B enable faulty usage-based-disturbance data 218 to be detected based on an occurrence of the engine 216 accessing a row while the address comparator 804-1 to 804-B enables faulty usage-based-disturbance data 218 to be detected based on an occurrence of an array counter update procedure. As seen in FIGS. 8-11, indirect address logging 800 enables the memory device 108 to be implemented with a less complicated interface 602 and is associated with a smaller die-size penalty compared to direct address logging 700 shown in FIG. 7. Indirect address logging 800 also avoids conflict resolution by controlling the reporting of faults based on an order in which the engine 216 accesses the rows 302.

FIG. 12 illustrates example implementations of the usage-based-disturbance data repair circuitry 122 and the mode register 214 for handling faulty usage-based-disturbance data. In the depicted configuration, the mode register 214 includes operands 1202-1, 1202-2, and 1202-3. Other implementations are also possible in which the operands 1202-1, 1202-2, and 1202-3 are associated with different mode registers 214. Aspects of handling faulty usage-based-disturbance data 218 involve the memory device 108 reporting an error to the host device 108 by updating the values stored by the operands 1201-1, 1202-2, and 1202-3. In example implementations, the host device 108 handles clearing a reported error. To avoid overwriting a previously-reported error, the memory device 108 does not report a new error until the host device 108 has cleared the previously-reported error.

The operand 1202-1 stores a value indicative of an event flag 1204. The event flag 1204 indicates if an error is detected at the local-bank level 128. The usage-based-disturbance data repair circuitry 122 can set the event flag 1204 prior to setting the report flag 610 and/or the address 608 in the case of indirect address logging 800, as further described below. In the case of direct address logging 700, the memory device 108 may or may not use or support an event flag 1204 as the address 608 can be directly passed to the global-bank level 130 based on the detection of the error.

The operand 1202-2 stores a value indicative of the report flag 610. In general, the report flag 610 indicates if the address 608 associated with the detected error is latched at the global-bank level 130. In other words, the report flag 610 indicates that an error (and the information associated with the error) is reported by the memory device 108 and is available for access by the host device 104.

The operand 1202-3 stores a value indicative of the address 608 that is associated with the detected error. For example, the address 608 can represent the address 608 of a row 302 corresponding to the faulty usage-based-disturbance data 218. In this example, the operand 1202-3 accepts (or latches) the address 608 provided by the address logging circuit 126 based on the report flag 610. This ensures that the memory device 108 does not overwrite an address 608 of a previously-reported error that has yet to be handled by (e.g., or cleared) the host device 104.

The usage-based-disturbance data repair circuitry 122 includes at least one logic gate 1206, which is depicted as an AND gate in this example. The logic gate 1206 ensures that the memory device 108 does not overwrite information associated with a previously-reported error. More specifically, the logic gate 1206 does not write new information to the mode register 214 unless the report flag 610 is clear (or previously cleared by the host device 104). In this case, the logic gate 1206 sets the report flag 610 based, at least in part, on the report flag 610 stored by the operand 1202-2. For example, the logic gate 1206 can set the report flag 610 to a second value of “1” if the previous value of the report flag 610, as stored by the operand 1202-2, is a first value of “0.”

Consider an example in which the memory device 108 uses indirect address logging 800. During operation, the usage-based-disturbance data repair circuitry 122 generates the composite control signal 606, which in this example can include the event flag 1204 and a match flag 1208. The event flag 1204 indicates one of the detection circuits 124 has detected an error associated with the usage-based-disturbance data 218. This can occur in a first time interval during which the detection circuit 124 performs the error detection test. In some situations, the detection circuit 124 performs the error detection test based on a row 302 being activated in accordance with a read or write command that is received from the host device 104. In some implementations, the error detection test is performed as part of an array counter update procedure. The mode register 214 updates a value of the operand 1202-1 based on the event flag 1204. In this way, the memory device 108 can inform the host device 104 that an error has been detected and that it is in the process of reporting the address 608 associated with the error.

In the case of indirect address logging 800, the match flag 1208 can be provided during a second time interval once the row is accessed via the engine 216. During this time interval, the engine 216 can perform an error-correcting code check on the normal data 306 associated with the row 302. The match flag 1208 indicates if the address comparator 804 has determined that an address 304 of the activated row 302 matches an address 608 that was previously logged at the local-bank level 128 and is associated with an error. The match flag 1208 can have a first value (e.g., a logic value of “0”), which indicates a match has not been found. Alternatively, the match flag 1208 can have a second value (e.g., a logic value of “1”), which indicates a match has been found.

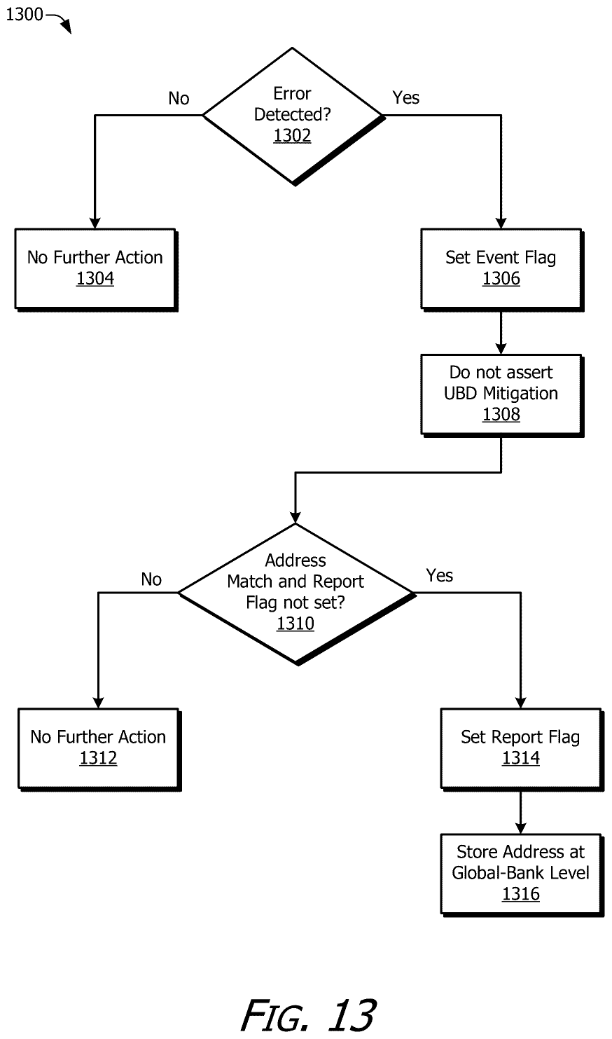

The usage-based-disturbance data repair circuitry 122 generates the report flag 610 based on the match flag 1208 and the value of the operand 1202-2. If the value of the operand 1202-2 indicates that the memory device 108 can report the error (e.g., the logic value of the operand 1202-2 is “0”), the usage-based-disturbance data repair circuitry 122 sets the report flag 610 to a second value (e.g., a logic value of “1”). This enables the register 214 to latch the address 608 provided by the address logging circuit 126. In this manner, the memory device 108 can ensure a previously-reported error is not overwritten. If the report flag 610 was previously set and has yet to be cleared by the host device 104, the memory device 108 foregoes reporting the error. The memory device 108 can also take further action to ensure operations for mitigating usage-based disturbance are not taken based on faulty usage-based-disturbance data 218, as further described with respect to FIG. 13.

FIG. 13 illustrates an example scheme 1300 implemented by the memory device 108 for handling faulty usage-based-disturbance data 218. At 1300, the detection circuit 124 performs the error detection test. If the detection circuit 124 does not detect an error, the usage-based-disturbance data repair circuitry 122 does not take any further action, as indicated at 1304. Otherwise, if the detection circuit 124 detects an error, the usage-based-disturbance data repair circuitry 122 sets the event flag 1204, as indicated at 1306.

At 1308, the usage-based-disturbance data repair circuitry 122 causes the usage-based-disturbance circuitry 120 to not assert an operation associated with usage-based-disturbance mitigation based on the determined faulty usage-based-disturbance data 218. This prevents the memory device 108 from refreshing rows 302 that are proximate to the row 302 corresponding to the faulty usage-based-disturbance data 218 even if the activation count 308 of the row 302 exceeds the mitigation threshold. As such, the memory device 108 can conserve resources for refreshing rows based on valid usage-based-disturbance data 218. There are a variety of different techniques that can be performed to avoid refreshing rows 302 based on the faulty usage-based-disturbance data 218.

In a first example, the event flag 1306 causes the usage-based-disturbance circuitry 120 to set the faulty usage-based-disturbance data 218 to a default value. The default value can be any value that is less than the mitigation threshold. For example, the usage-based-disturbance circuitry 120 can set the activation count 308 of the row 302 to zero.

In a second example, consider that the faulty usage-based-disturbance data 218 included an activation count 308 that is greater than the mitigation threshold. As such, the usage-based-disturbance circuitry 120 stored the address 304 corresponding to the usage-based-disturbance data 218 in a queue. In this case, the event flag 1204 causes the usage-based-disturbance circuitry 120 to remove the address 304 of the row 302 associated with the faulty usage-based-disturbance data 218 from the queue. This ensures that the usage-based-disturbance circuitry 120 does not initiate refreshing of one or more victim rows that are proximate to the address 304.

At 1310, the usage-based-disturbance data repair circuitry 122 determines if the address 810 latched at the global-bank level 130 matches the address 608 that is previously logged at the local-bank level 128 based on the match flag 1208 provided by the detection circuit 124. The usage-based-disturbance data repair circuitry 122 also determines if the report flag is not set. If either condition is false, the usage-based-disturbance data repair circuitry 122 takes no further action, as indicated at 1312. The usage-based-disturbance data repair circuitry 122 can continue to monitor for one of these conditions to change at 1310. Alternatively, if both conditions are true, the usage-based-disturbance data repair circuitry 122 sets the report flag 610 at 1314. At 1316, the address 608 is stored at the global-bank level 130. This storage can be based on the setting of the report flag 610, as described above with respect to FIG. 12. The information that is reported about a detected error and is stored within the mode register 214 can be accessed by the host device 104, as further described with respect to FIG. 14.

FIG. 14 illustrates an example of a system 1400 that includes a host device 104 and a memory device 108 that are coupled together via an interconnect 106. The system 1400 may form at least part of an apparatus 102 as shown in FIG. 1. As illustrated, the host device 104 includes a processor 110 and a link controller 1402, which can be realized with at least one initiator 1404. Thus, the initiator 1404 can be coupled to the processor 110 or to the interconnect 106 (including to both), and the initiator 1404 can be coupled between the processor 110 and the interconnect 106. Examples of initiators 1404 may include a leader, a primary, a master, a main component, and so forth.

In the illustrated example system 1400, the memory device 108 includes a link controller 1406, which may be realized with at least one target 1408. The target 1408 can be coupled to the interconnect 106. Thus, the target 1408 and the initiator 1404 can be coupled to each other via the interconnect 106. Example targets 1408 may include a follower, a secondary, a slave, a responding component, and so forth. The memory device 108 also includes a memory, which may be realized with at least one memory module 402 or other component, such as a DRAM 1410, as is described further below.

In example implementations, the initiator 1404 includes the link controller 1402, and the target 1408 includes the link controller 1406. The link controller 1402 or the link controller 1406 can instigate, coordinate, cause, or otherwise control signaling across a physical or logical link realized by the interconnect 106 in accordance with one or more protocols. The link controller 1402 may be coupled to the interconnect 106. The link controller 1406 may also be coupled to the interconnect 106. Thus, the link controller 1402 can be coupled to the link controller 1406 via the interconnect 106. Each link controller 1402 or 1406 may, for instance, control communications over the interconnect 106 at a link layer or at one or more other layers of a given protocol. Communication signaling may include, for example, a request 1412 (e.g., a write request or a read request), a response 1414 (e.g., a write response or a read response), and so forth.

The memory device 108 may further include at least one interconnect 1416 and at least one memory controller 1418 (e.g., MC 1418-1 and MC 1418-2). Within the memory device 108, and relative to the target 1408, the interconnect 1416, the memory controller 1418, and/or the DRAM 1410 (or other memory component) may be referred to as a “backend” component of the memory device 108. In some cases, the interconnect 1416 is internal to the memory device 108 and may operate in a manner the same as or different from the interconnect 106.

As shown, the memory device 108 may include multiple memory controllers 1418-1 and 1418-2 and/or multiple DRAMs 1410-1 and 1410-2. Although two each are shown, the memory device 108 may include one or more memory controllers 1418 and/or one or more DRAMs 1410. For example, a memory device 108 may include four memory controllers 1418 and sixteen DRAMs 1410, such as four DRAMs 1410 per memory controller 1418. The memory components of the memory device 108 are depicted as DRAM 1410 only as an example, for one or more of the memory components may be implemented as another type of memory. For instance, the memory components may include nonvolatile memory like flash or phase-change memory. Alternatively, the memory components may include other types of volatile memory like static random-access memory (SRAM). A memory device 108 may also include any combination of memory types. In example implementations, the DRAM 1410-1 and/or the DRAM 1410-2 include mode registers 214-1 and 214-2, respectively.

In some cases, the memory device 108 may include the target 1408, the interconnect 1416, the at least one memory controller 1418, and the at least one DRAM 1410 within a single housing or other enclosure. The enclosure, however, may be omitted or may be merged with an enclosure for the host device 104, the system 1400, or an apparatus 102 (of FIG. 1). The interconnect 1416 can be disposed on a printed circuit board. Each of the target 1408, the memory controller 1418, and the DRAM 1410 may be fabricated on at least one integrated circuit and packaged together or separately. The packaged integrated circuits may be secured to or otherwise supported by the printed circuit board and may be directly or indirectly coupled to the interconnect 1416. In other cases, the target 1408, the interconnect 1416, and the one or more memory controllers 1418 may be integrated together into one integrated circuit. In some of such cases, this integrated circuit may be coupled to a printed circuit board, and one or more modules for the memory components (e.g., for the DRAM 1410) may also be coupled to the same printed circuit board, which can form a CXL type of memory device 108. This memory device 108 may be enclosed within a housing or may include such a housing. The components of the memory device 108 may, however, be fabricated, packaged, combined, and/or housed in other manners.

As illustrated in FIG. 14, the target 1408, including the link controller 1406 thereof, can be coupled to the interconnect 1416. Each memory controller 1418 of the multiple memory controllers 1418-1 and 1418-2 can also be coupled to the interconnect 1416. Accordingly, the target 1408 and each memory controller 1418 of the multiple memory controllers 1418-1 and 1418-2 can communicate with each other via the interconnect 1416. Each memory controller 1418 is coupled to at least one DRAM 1410. As shown, each respective memory controller 1418 of the multiple memory controllers 1418-1 and 1418-2 is coupled to at least one respective DRAM 1410 of the multiple DRAMs 1410-1 and 1410-2. Each memory controller 1418 of the multiple memory controllers 1418-1 and 1418-2 may, however, be coupled to a respective set of multiple DRAMs 1410 (e.g., five DRAMs 1410) or other memory components.

Each memory controller 1418 can access at least one DRAM 1410 by implementing one or more memory access protocols to facilitate reading or writing data based on at least one memory address. The memory controller 1418 can increase bandwidth or reduce latency for the memory accessing based on the memory type or organization of the memory components, like the DRAMs 1410. The multiple memory controllers 1418-1 and 1418-2 and the multiple DRAMs 1410-1 and 1410-2 can be organized in many different manners. For example, each memory controller 1418 can realize one or more memory channels for accessing the DRAMs 1410. Further, the DRAMs 1410 can be manufactured to include one or more ranks, such as a single-rank or a dual-rank memory module. Each DRAM 1410 (e.g., at least one DRAM IC chip) may also include multiple banks, such as 8 or 16 banks.

This document now describes examples of the host device 104 accessing the memory device 108. The examples are described in terms of a general access which may include a memory read access (e.g., a retrieval operation) or a memory write access (e.g., a storage operation). The processor 110 can provide a memory access request 1420 to the initiator 1404. The memory access request 1420 may be propagated over a bus or other interconnect that is internal to the host device 104. This memory access request 1420 may be or may include a read request or a write request. The initiator 1404, such as the link controller 1402 thereof, can reformulate the memory access request 1420 into a format that is suitable for the interconnect 106. This formulation may be performed based on a physical protocol or a logical protocol (including both) applicable to the interconnect 106. Examples of such protocols are described below.

The initiator 1404 can thus prepare a request 1412 and transmit the request 1412 over the interconnect 106 to the target 1408. The target 1408 receives the request 1412 from the initiator 1404 via the interconnect 106. The target 1408, including the link controller 1406 thereof, can process the request 1412 to determine (e.g., extract or decode) the memory access request 1420. Based on the determined memory access request 1420, the target 1408 can forward a memory request 1422 over the interconnect 1416 to a memory controller 1418, which is the first memory controller 1418-1 in this example. For other memory accesses, the targeted data may be accessed with the second DRAM 1410-2 through the second memory controller 1418-2.

The first memory controller 1418-1 can prepare a memory command 1424 based on the memory request 1422. The first memory controller 1418-1 can provide the memory command 1424 to the first DRAM 1410-1 over an interface or interconnect appropriate for the type of DRAM or other memory component. The first DRAM 1410-1 receives the memory command 1424 from the first memory controller 1418-1 and can perform the corresponding memory operation. The memory command 1424, and corresponding memory operation, may pertain to a read operation, a write operation, a refresh operation, and so forth. Based on the results of the memory operation, the first DRAM 1410-1 can generate a memory response 1426. If the memory request 1422 is for a read operation, the memory response 1426 can include the requested data. If the memory request 1422 is for a write operation, the memory response 1426 can include an acknowledgment that the write operation was performed successfully. The first DRAM 1410-1 can return the memory response 1426 to the first memory controller 1418-1.

The first memory controller 1418-1 receives the memory response 1426 from the first DRAM 1410-1. Based on the memory response 1426, the first memory controller 1418-1 can prepare a memory response 1428 and transmit the memory response 1428 to the target 1408 via the interconnect 1416. The target 1408 receives the memory response 1428 from the first memory controller 1418-1 via the interconnect 1416. Based on this memory response 1428, and responsive to the corresponding request 1412, the target 1408 can formulate a response 1430 for the requested memory operation. The response 1430 can include read data or a write acknowledgment and be formulated in accordance with one or more protocols of the interconnect 106.

To respond to the request 1412 from the host device 104, the target 1408 can transmit the response 1430 to the initiator 1404 over the interconnect 106. Thus, the initiator 1404 receives the response 1430 from the target 1408 via the interconnect 106. The initiator 1404 can therefore respond to the “originating” memory access request 1420, which is from the processor 110 in this example. To do so, the initiator 1404 prepares a memory access response 1432 using the information from the response 1430 and provides the memory access response 1432 to the processor 110. In this way, the host device 104 can obtain memory access services from the memory device 108 using the interconnect 106. Example aspects of an interconnect 106 are described next.

The interconnect 106 can be implemented in a myriad of manners to enable memory-related communications to be exchanged between the initiator 1404 and the target 1408. Generally, the interconnect 106 can carry memory-related information, such as data or a memory address, between the initiator 1404 and the target 1408. In some cases, the initiator 1404 or the target 1408 (including both) can prepare memory-related information for communication across the interconnect 106 by encapsulating such information. The memory-related information can be encapsulated into, for example, at least one packet (e.g., a flit). One or more packets may include headers with information indicating or describing the content of each packet.

In example implementations, the interconnect 106 can support, enforce, or enable memory coherency for a shared memory system, for a cache memory, for combinations thereof, and so forth. Additionally or alternatively, the interconnect 106 can be operated based on a credit allocation system. Possession of a credit can enable an entity, such as the initiator 1404, to transmit another memory request 1412 to the target 1408. The target 1408 may return credits to “refill” a credit balance at the initiator 1404. A credit-based communication scheme across the interconnect 106 may be implemented by credit logic of the target 1408 or by credit logic of the initiator 1404 (including by both working together in tandem).

The system 1400, the initiator 1404 of the host device 104, or the target 1408 of the memory device 108 may operate or interface with the interconnect 106 in accordance with one or more physical or logical protocols. For example, the interconnect 106 may be built in accordance with a Peripheral Component Interconnect Express (PCIe or PCI-e) standard. Applicable versions of the PCIe standard may include 1.x, 2.x, 3.x, 14.0, 5.0, 6.0, and future or alternative versions. In some cases, at least one other standard is layered over the physical-oriented PCIe standard. For example, the initiator 1404 or the target 1408 can communicate over the interconnect 106 in accordance with a Compute Express Link (CXL) standard. Applicable versions of the CXL standard may include 1.x, 2.0, and future or alternative versions. The CXL standard may operate based on credits, such as read credits and write credits. In such implementations, the link controller 1402 and the link controller 1406 can be CXL controllers.

For handling faulty usage-based-disturbance data, the system 1400 enables the DRAM 1410-1 and 1410-2 to report an error associated with usage-based-disturbance data 218 to the host device 104. For example, the host device 104 can send a mode-register-read command (MRR command) via a request 1412 to read the report flag 610, the address 608, and/or the event flag 1204 that is stored within the mode registers 214-1 and/or 214-2. In this case, the memory device 108 provides the information associated with the report flag 610, the address 608, and/or the event flag 1204 via the response 1430.

To address a reported error, the host device 104 can send repair command via a request 1412 to the memory device 108. The repair command causes the memory device 108 to perform a repair operation that addresses (e.g., fixes) the error associated with the usage-based-disturbance data 218. Additionally or alternatively, the host device 104 can send a mode-register-write command via a request 1412 to clear the report flag 610, the address 608, and/or the event flag 1204. This enables the memory device 108 to report a second error that has already been detected and logged at the local-bank level 128 or to report a third error that is detected at a later point in time.

### Example Methods

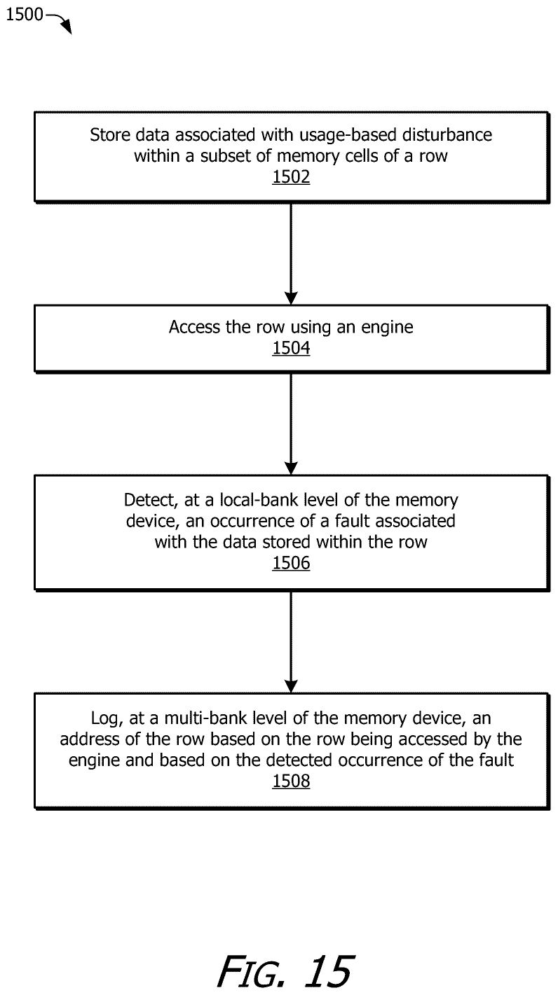

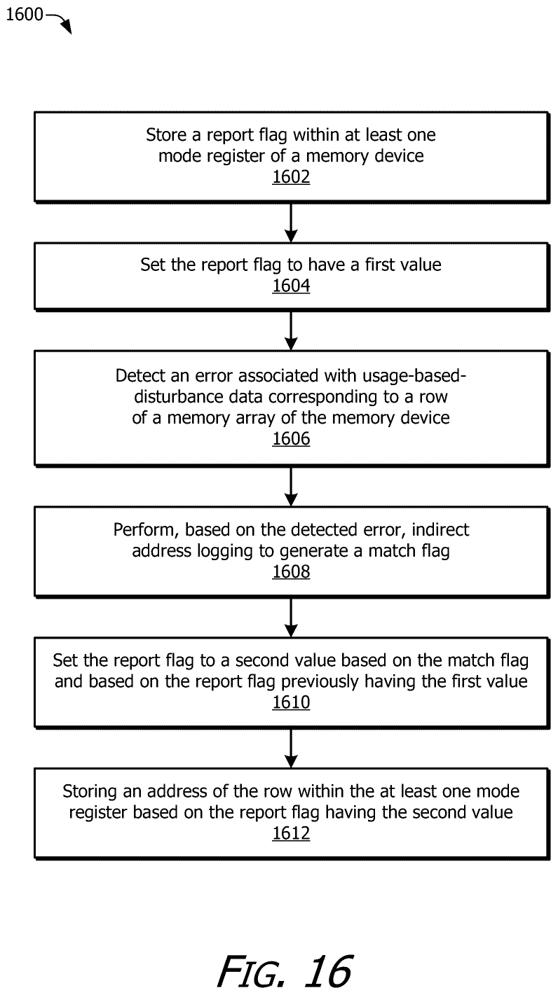

This section describes example methods for implementing aspects of handling faulty usage-based-disturbance data with reference to the flow diagrams of FIGS. 15 and 16. These descriptions may also refer to components, entities, and other aspects depicted in FIGS. 1 to 14 by way of example only. The described method is not necessarily limited to performance by one entity or multiple entities operating on one device.

FIG. 15 illustrates a method 1500, which includes operations 1502 through 1508. In aspects, operations of the method 1500 are implemented by a memory device 108 as described with reference to FIG. 1. At 1502, data associated with usage-based disturbance is stored within a subset of memory cells of a row. For example, the row 302 stores the usage-based-disturbance data 218 within a subset of the memory cells. The usage-based-disturbance data 218 can be accessed by the usage-based disturbance circuitry 120 and used to mitigate usage-based disturbance. In an example implementation, the usage-based-disturbance data 218 represents an activation count 308. In some implementations, the host device 104 (e.g., the memory controller 114) does not have access to the usage-based-disturbance data 218.

At 1504, the row is accessed using an engine. For example, the engine 216 accesses the row 302. The engine 216 can access to the row and perform an operation on the normal data 306 that is stored within another subset of the memory cells of the row 302. In an example implementation, the engine 216 is implemented as an error check and scrub engine, which can detect errors within the normal data 306. In some implementations, the engine 216 does not directly perform operations associated with usage-based disturbance mitigation or does not perform operations on the usage-based-disturbance data 218.

In general, the engine 216 is capable of accessing all of the rows 302 within the memory array 204. This enables the techniques associated with indirect address logging 800 to report the occurrence of faults associated with the usage-based-disturbance data 218 in a controlled manner that avoids conflicts across multiple banks 410.

At 1506, an occurrence of a fault associated with the data stored within the row is detected at a local-bank level of the memory device. For example, the usage-based-disturbance data repair circuitry 122 detects, at the local-bank level, the occurrence of the fault associated with the usage-based-disturbance data 218 that is stored within the row 302. In some implementations, the usage-based-disturbance data repair circuitry 122 can directly detect the fault by executing an error detection test at the local-bank level. The error detection test can be performed based on an occurrence of a procedure performed by the usage-based disturbance circuitry 120 to update the usage-based-disturbance data 218 and/or based on an occurrence of the engine 216 accessing the row 302. In other implementations, the usage-based disturbance circuitry 120 can directly detect the fault by executing the error detection test and provide an indication to the usage-based-disturbance data repair circuitry 122 if the fault is detected.

At 1508, an address of the row is logged, at a global-bank level of the memory device, based on the row being accessed by the engine and based on the detected occurrence of the fault. For example, the usage-based-disturbance data repair circuitry 122 logs, at the global-bank level 130 of the memory device 108, the address 608 of the row 302 based on the row 302 being accessed by the engine 216 and based on the detected occurrence of the fault, which is reported from (or indicated by) the local-bank level 128 to the global-bank level 130. In particular, the usage-based-disturbance data repair circuitry 122 can latch the address 810 that is accessed by the engine 216 based on the local-bank level 128 indicating occurrence of a fault that is associated with the address 810. The usage-based-disturbance data repair circuitry 122 can store the latched address 608 and/or the report flag 610 in one or more mode registers of the mode register 214, which can be accessed by the host device 104. With this information, the host device 104 can initiate a repair procedure that addresses the detected fault associated with the usage-based-disturbance data 218 stored within the row 302.

FIG. 16 illustrates a method 1600, which includes operations 1602 through 1612. In aspects, operations of the method 1600 are implemented by a memory device 108 as described with reference to FIG. 1. At 1602, a report flag is stored within at least one mode register of a memory device. For example, the mode register 214 stores the report flag 610, as shown in FIG. 12.

At 1604, the report flag is set to have a first value. For example, the memory device 108 sets the report flag 610 to have a first value. In a first example, the first value indicates an absence of an error report. In this situation, the memory device 108 has yet to detect an error (or another error) associated with the usage-based-disturbance data 218. In some situations, the memory device 108 sets the report flag 610 to have the first value based on a mode-register-write command sent by the host device 104. In this case, the mode-register-write command causes the memory device 108 to clear the report flag 610 (e.g., set the report flag 610 to a default value, which is represented by the first value). In an example implementation, the first value represents a logic value of “0.”

At 1606, an error associated with usage-based-disturbance data corresponding to a row of a memory array of a memory device is detected. For example, the usage-based-disturbance data repair circuitry 122, or more specifically a detection circuit 124, detects an error associated with usage-based-disturbance data 218 corresponding to a row 302 of the memory array 204, as shown in FIGS. 2 and 3. The detection circuit 124 can perform a variety of error detection tests to detect the error. Example tests include a parity bit check, an error-correcting-code check, a checksum check, and/or a cyclic redundancy check.

To perform the parity bit check, the detection circuit 124 determines a parity of the usage-based-disturbance data 218 corresponding to the row 302. The detection circuit 124 compares the determined parity of the usage-based-disturbance data 218 to the parity bit 310 corresponding to the usage-based-disturbance data 218. If the parity and the parity bit 310 differ, the detection circuit 124 detects a parity error.

At 1608, indict address logging is performed to generate a match flag. The indirect address logging is performed based on the detected error. For example, the usage-based-disturbance data repair circuitry 122 performs indirect address logging 800 to generate the match flag 1208, as shown in FIG. 12. The match flag 1208 indicates that an address 810 of a row 302 that is accessed using the engine 216 and is latched at the global-bank level 130 (e.g., latched via the latch circuit 808) matches (e.g., is the same as) an address 608 that is logged at the local-bank level 128 (e.g., logged via the content-addressable memory 1004). The match flag 1208 can have a first value (e.g., a logic value of “0”) to indicate that a match has not been found at 1310 in FIG. 13. Alternatively, the match flag 1208 can have a second value (e.g., a logic value of “1”) to indicate that a match has been found at 1310.

At 1610, the report flag is set to have a second value based on the match flag and based on the report flag previously having the first value. For example, the usage-based-disturbance data repair circuitry 122 sets the report flag 610 to have the second value. More specifically, the logic gate 1206 sets the report flag 610 to have the second value based on the match flag 1208 and based on the previous value of the report flag 610, which is stored by the operand 1202-2 of the mode register 214, as shown in FIG. 12. The second value indicates that the address 608 of the row 302 has been logged at the global-bank level 130 for indirect address logging 800. The second value can represent a logic value of “1,” in example implementations. In this case, the report flag 610 is not set if there is a previously-reported error that the host device 104 has not cleared. In this manner, the information about a previously-reported error is not overwritten by the memory device 108.

At 1612, an address of the row is stored within the at least one mode register based on the report flag having the second value. For example, the mode register 214 stores the address 608 of the row 302 based on the report flag 610 having the second value. This ensures that the address 608 associated with a previously-reported error is not overwritten.

For the figure described above, the order in which operations are shown and/or described are not intended to be construed as a limitation. Any number or combination of the described process operations can be combined or rearranged in any order to implement a given method or an alternative method. Operations may also be omitted from or added to the described methods. Further, described operations can be implemented in fully or partially overlapping manners.

Aspects of this method may be implemented in, for example, hardware (e.g., fixed-circuit circuitry or a processor in conjunction with a memory), firmware, software, or some combination thereof. The method may be realized using one or more of the apparatuses or components shown in FIGS. 1 to 11, the components of which may be further divided, combined, rearranged, and so on. The devices and components of these figures generally represent hardware, such as electronic devices, packaged modules, IC chips, or circuits; firmware or the actions thereof; software; or a combination thereof. Thus, these figures illustrate some of the many possible systems or apparatuses capable of implementing the described methods.

Computer-readable media includes both non-transitory computer storage media and communication media including any medium that facilitates transfer of a computer program (e.g., an application) or data from one entity to another. Non-transitory computer storage media can be any available medium accessible by a computer, such as RAM, ROM, Flash, EEPROM, optical media, and magnetic media.

In the following, various examples for implementing aspects of handling faulty usage-based-disturbance data are described:
Example 1: A method performed by a memory device, the method comprising: storing a report flag within at least one mode register of the memory device;
   setting the report flag to have a first value;
   detecting an error associated with usage-based-disturbance data corresponding to a row of a memory array of the memory device;
   performing, based on the detecting of the error, indirect address logging to generate a match flag;
   setting the report flag to a second value based on the match flag and based on the report flag previously having the first value; and
   storing an address of the row within the at least one mode register based on the report flag having the second value.
Example 2: The method of example 1 or any other example, further comprising: storing an event flag within the at least one mode register;
   setting the event flag to have the first value; and
   responsive to the detecting of the error, setting the event flag to have the second value.
Example 3: The method of example 2 or any other example, further comprising: receiving at least one mode-register-write command from a host device that is coupled to the memory device;
   setting the report flag and the event flag to the first value based on the at least one mode-register-write command; and
   clearing the address stored within the at least one mode register based on the at least one mode-register-write command.
Example 4: The method of example 3 or any other example, further comprising:
   prior to the receiving of the at least one mode-register-write command, detecting a second error associated with usage-based-disturbance data corresponding to a second row of the memory array; and foregoing reporting the second error to the host device based on the report flag having the second value.
Example 5: The method of example 3 or any other example, further comprising: detecting a third error associated with usage-based-disturbance data corresponding to a third row of the memory array, the detecting of the third error occurring after the setting of the report flag and the event flag to the first value based on the at least one mode-register-write command;
   performing, based on the detecting of the third error, the indirect address logging to generate the match flag;
   setting the report flag to the second value based on the match flag being generated based on the detected third error, and based on the report flag previously having the first value; and
   storing an address of the third row within the at least one mode register based on the report flag having the second value.
Example 6: The method of example 1 or any other example, further comprising: responsive to the detecting of the error, preventing the usage-based-disturbance data corresponding to the row from initiating an operation associated with mitigating usage-based disturbance.
Example 7: The method of example 6 or any other example, wherein the preventing of the usage-based-disturbance data from initiating the operation associated with mitigating usage-based disturbance comprises writing a default value to the usage-based-disturbance data corresponding to the row, the default value being less than a mitigation threshold.
Example 8: The method of example 1 or any other example, further comprising:
   responsive to the detecting of the error, logging an address of the row at a local-bank level of the memory device; and
   accessing the row using an engine,
   wherein the performing of the indirect address logging comprises:
      latching, at a global-bank level of the memory device, the address of the accessed row responsive to the row being accessed using the engine; and
      setting the match flag to the second value responsive to the address of the accessed row matching the address logged at the local-bank level.
Example 9: The method of example 8 or any other example, wherein: the engine comprises an error-check and scrub engine; and the method further comprises performing, using the error-check and scrub engine, error detection on other data corresponding to the row.
Example 10: The method of example 1 or any other example, further comprising: receiving a write command or a read command from a host device; and responsive to receiving the write command or the read command, activating the row, wherein the detecting of the error is based on the activating of the row.
Example 11: The method of example 10, further comprising:
   performing an array counter update procedure based on the activating of the row; and
   performing an error detection test on the usage-based-disturbance data as part of the array counter update procedure.
Example 12: The method of example 11 or any other example, wherein the performing of the error detection test comprises at least one of the following:
   performing a parity bit check;
   performing an error-correcting-code check;
   performing a checksum check; or performing a cyclic redundancy check.
Example 13: A memory device comprising:
   a memory array comprising a row;
   at least one mode register, the at least one mode register configured to:
      store a report flag having a first value; and
      store a latched address; and
   a circuit coupled to the memory array and the at least one mode register, the circuit configured to:
      detect an error associated with usage-based-disturbance data corresponding to the row;
      perform, based on the detected error, indirect address logging to generate a match flag;
      latch an address of the row at a global-bank level of the memory device;
      set the report flag to a second value based on the match flag and based on the report flag previously having the first value; and
      cause the at least one mode register to store the address of the row as the latched address based on the report flag having the second value.
Example 14: The memory device of example 13 or any other example, wherein the memory device is configured to:
   receive at least one mode-register-write command from a host device that is coupled to the memory device;
   set the report flag to the first value based on the at least one mode-register-write command; and
   clear the latched address from the at least one mode register based on the at least one mode-register-write command.
Example 15: The memory device of example 14 or any other example, wherein:
   the memory array comprises a second row; and
   the circuit is configured to:
      detect, prior to the reception of the mode-register-write command, a second error associated with usage-based-disturbance data corresponding to the second row; and
      forego reporting the second error to the host device based on the report flag having the second value.
Example 16: The memory device of example 14 or any other example, wherein: the memory array comprises a third row; and the circuit is configured to:
   detect, after the memory device sets the report flag to the first value based on the at least one mode-register-write command, a third error associated with usage-based-disturbance data corresponding to the third row;
   perform, based on the detected third error, indirect address logging to generate the match flag;
   latch an address of the third row at a global-bank level of the memory device;
   set the report flag to the second value based on the match flag being generated based on the detected third error, and based on the report flag previously having the first value; and
   cause the at least one mode register to store the address of the third row as the latched address based on the report flag having the second value.
Example 17: The memory device of example 13 or any other example, wherein the circuit is configured to detect the error by performing at least one of the following:
   a parity bit check;
   an error-correcting-code check;
   a checksum check; or
   a cyclic redundancy check.
Example 18: A method performed by a memory device, the method comprising:
   detecting an error associated with usage-based-disturbance data corresponding to a row; and
   responsive to the detecting of the error, preventing usage-based-disturbance mitigation from being performed based on the usage-based-disturbance data corresponding to the row.
Example 19: The method of example 18 or any other example, wherein the preventing of the usage-based-disturbance mitigation for the row comprises preventing an activation count of the row from causing other rows that are proximate to the row to be refreshed for usage-based-disturbance mitigation.
Example 20: The method of example 18 or any other example, further comprising:
   receiving, from a host device, a command to repair the row;
   responsive to the receiving of the command, repairing the row; and
   enabling usage-based-disturbance mitigation to be performed based on the usage-based-disturbance data corresponding to the row responsive to the repairing of the row.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

### CONCLUSION

Although aspects of handling faulty usage-based-disturbance data have been described in language specific to certain features and/or methods, the subject of the appended claims is not necessarily limited to the specific features or methods described. Rather, the specific features and methods are disclosed as a variety of example implementations of handling faulty usage-based-disturbance data.

What is claimed is:

1. A method performed by a memory device, the method comprising:
storing a report flag within at least one mode register of the memory device;
setting the report flag to have a first value;
detecting an error associated with usage-based-disturbance data corresponding to a row of a memory array of the memory device;
performing, based on the detecting of the error, indirect address logging to generate a match flag;
setting the report flag to a second value based on the match flag and based on the report flag previously having the first value; and
storing an address of the row within the at least one mode register based on the report flag having the second value.

2. The method of claim 1, further comprising:
storing an event flag within the at least one mode register;
setting the event flag to have the first value; and
responsive to the detecting of the error, setting the event flag to have the second value.

3. The method of claim 2, further comprising:
receiving at least one mode-register-write command from a host device that is coupled to the memory device;
setting the report flag and the event flag to the first value based on the at least one mode-register-write command; and
clearing the address stored within the at least one mode register based on the at least one mode-register-write command.

4. The method of claim 3, further comprising:
prior to the receiving of the at least one mode-register-write command, detecting a second error associated with usage-based-disturbance data corresponding to a second row of the memory array; and
foregoing reporting the second error to the host device based on the report flag having the second value.

5. The method of claim 3, further comprising:
detecting a third error associated with usage-based-disturbance data corresponding to a third row of the memory array, the detecting of the third error occurring after the setting of the report flag and the event flag to the first value based on the at least one mode-register-write command;
performing, based on the detecting of the third error, the indirect address logging to generate the match flag;
setting the report flag to the second value based on the match flag being generated based on the detected third error, and based on the report flag previously having the first value; and
storing an address of the third row within the at least one mode register based on the report flag having the second value.

6. The method of claim 1, further comprising:
responsive to the detecting of the error, preventing the usage-based-disturbance data corresponding to the row from initiating an operation associated with mitigating usage-based disturbance.

7. The method of claim 6, wherein the preventing of the usage-based-disturbance data from initiating the operation associated with mitigating usage-based disturbance comprises writing a default value to the usage-based-disturbance data corresponding to the row, the default value being less than a mitigation threshold.

8. The method of claim 1, further comprising:
responsive to the detecting of the error, logging an address of the row at a local-bank level of the memory device; and
accessing the row using an engine,
wherein the performing of the indirect address logging comprises:
latching, at a global-bank level of the memory device, the address of the accessed row responsive to the row being accessed using the engine; and
setting the match flag to the second value responsive to the address of the accessed row matching the address logged at the local-bank level.

9. The method of claim 8, wherein:
the engine comprises an error-check and scrub engine; and
the method further comprises performing, using the error-check and scrub engine, error detection on other data corresponding to the row.

10. The method of claim 1, further comprising:
receiving a write command or a read command from a host device; and
responsive to receiving the write command or the read command, activating the row,
wherein the detecting of the error is based on the activating of the row.

11. The method of claim 10, further comprising:
performing an array counter update procedure based on the activating of the row; and
performing an error detection test on the usage-based-disturbance data as part of the array counter update procedure.

12. The method of claim 11, wherein the performing of the error detection test comprises at least one of the following:
performing a parity bit check;
performing an error-correcting-code check;
performing a checksum check; or
performing a cyclic redundancy check.

13. A memory device comprising:
a memory array comprising a row;
at least one mode register, the at least one mode register configured to:
store a report flag having a first value; and
store a latched address; and
a circuit coupled to the memory array and the at least one mode register, the circuit configured to:
detect an error associated with usage-based-disturbance data corresponding to the row;
perform, based on the detected error, indirect address logging to generate a match flag;
latch an address of the row at a global-bank level of the memory device;
set the report flag to a second value based on the match flag and based on the report flag previously having the first value; and
cause the at least one mode register to store the address of the row as the latched address based on the report flag having the second value.

14. The memory device of claim 13, wherein the memory device is configured to:
receive at least one mode-register-write command from a host device that is coupled to the memory device;
set the report flag to the first value based on the at least one mode-register-write command; and
clear the latched address from the at least one mode register based on the at least one mode-register-write command.

15. The memory device of claim 14, wherein:
the memory array comprises a second row; and
the circuit is configured to:
detect, prior to the reception of the mode-register-write command, a second error associated with usage-based-disturbance data corresponding to the second row; and
forego reporting the second error to the host device based on the report flag having the second value.

16. The memory device of claim 14, wherein:
the memory array comprises a third row; and
the circuit is configured to:
detect, after the memory device sets the report flag to the first value based on the at least one mode-register-write command, a third error associated with usage-based-disturbance data corresponding to the third row;
perform, based on the detected third error, indirect address logging to generate the match flag;
latch an address of the third row at a global-bank level of the memory device;
set the report flag to the second value based on the match flag being generated based on the detected third error, and based on the report flag previously having the first value; and
cause the at least one mode register to store the address of the third row as the latched address based on the report flag having the second value.

17. The memory device of claim 13, wherein the circuit is configured to detect the error by performing at least one of the following:
a parity bit check;
an error-correcting-code check;
a checksum check; or
a cyclic redundancy check.

18. A method performed by a memory device, the method comprising:
detecting an error associated with usage-based-disturbance data corresponding to a row; and
responsive to the detecting of the error, preventing usage-based-disturbance mitigation from being performed based on the usage-based-disturbance data corresponding to the row.

19. The method of claim 18, wherein the preventing of the usage-based-disturbance mitigation for the row comprises preventing an activation count of the row from causing other rows that are proximate to the row to be refreshed for usage-based-disturbance mitigation.

20. The method of claim 18, further comprising:
receiving, from a host device, a command to repair the row;
responsive to the receiving of the command, repairing the row; and
enabling usage-based-disturbance mitigation to be performed based on the usage-based-disturbance data corresponding to the row responsive to the repairing of the row.
